(19) United States
(12) Patent Application Publication
(10) Pub. No.: US 2024/0376339 A1
(43) Pub. Date: Nov. 14, 2024

(54) PHOTOSENSITIVE POLYCYCLIC-OLEFINIC POLYMERS AND DIAZIRINE COMPOSITIONS FOR LOW-LOSS FILMS HAVING IMPROVED PROPERTIES

(71) Applicant: PROMERUS, LLC, Akron, OH (US)

(72) Inventors: Pramod KANDANARACHCHI, Akron, OH (US); Larry F. RHODES, Akron, OH (US)

(73) Assignee: PROMERUS, LLC, Akron, OH (US)

(21) Appl. No.: 18/660,603

(22) Filed: May 10, 2024

Related U.S. Application Data
(60) Provisional application No. 63/465,482, filed on May 10, 2023.

(51) Int. Cl. C09D 145/00; C08F 32/08; C09D 7/65; G03F 7/038

(52) U.S. Cl. CPC C09D 145/00; C08F 32/08; C09D 7/65; G03F 7/0382

(57) ABSTRACT

Embodiments in accordance with the present invention encompass compositions containing a polycycloolefinic polymer and at least one diazirine compound as described herein which when subjected to a suitable temperature or actinic radiation undergoes crosslinked network to form a three-dimensional insulating article which exhibits hitherto unattainable low dielectric constant and low-loss properties, and very high thermal properties. The compositions of this invention may additionally contain hydrogenated tackifiers, which provide much improved adhesive properties and are suitable in a number of opto-electronic applications including copper-clad laminates, among others. The compositions of this invention are also useful as insulating materials in millimeter wave radar antennas, among others.

### CROSS REFERENCE TO RELATED APPLICATIONS

This application claims the benefit of U.S. Provisional Application No. 63/465,482, filed May 10, 2023, which is incorporated herein by reference in its entirety.

### BACKGROUND OF THE INVENTION

### Field of the Invention

Embodiments in accordance with the present invention relate generally to a composition containing a polymer derived from polycycloolefinic monomers and a diazirine as described herein which when subjected to a suitable temperature and/or actinic radiation forms a crosslinked three-dimensional insulating article which exhibits hitherto unattainable low dielectric constant and low-loss properties, and very high thermal properties. More specifically, this invention relates to a composition containing a series of polymers derived from substituted norbornene derivatives and at least one multifunctional diazirine compound which undergoes crosslinking to form three-dimensional thermoset articles such as for example films, which exhibit very high glass transition temperature, which can be higher than 150° C., and exhibits low dielectric constant (less than 2.6 at a frequency of 10 GHZ) and low-loss properties. In some other embodiments the composition of this invention additionally contains hydrogenated tackifiers suitable in such applications as copper-clad laminates. Accordingly, the compositions of this invention find a variety of uses, including as insulating materials and are useful in a variety of applications including electromechanical devices having applications in the fabrication of a number of automotive parts, among others.

### Description of the Art

It is well known in the art that insulating materials having low dielectric constant (Dk) and low-loss, also referred to as dielectric dissipation factor, (Df) are important in printed circuit boards catering to electrical appliances and automotive parts and other applications. Generally, in most of such devices the insulating materials that are suitable must have dielectric constant lower than 3 and low-loss lesser than 0.003 at high frequencies such as for example greater than 50 GHz. Also, there is an increased interest in developing organic dielectric materials as they are easy to fabricate among other advantages.

However, there are significant technical challenges in developing such insulating materials meeting all of the requirements. One such challenge is that such materials exhibit low coefficient of thermal expansion (CTE), which is preferably less than 50 ppm/K due to concerns of peeling from copper layers. Another challenge is that such materials must exhibit very high glass transition temperature (T_{g}), which is preferably greater than 150° C. or even higher than 200° C. due to the process conditions used in the manufacture of printed circuit boards as well as harsh conditions the devices may encounter, such as for example millimeter-wave Radar antennas used in the automobiles.

Although films made from the addition polymerization of norbornene derivatives containing long side chains, such as for example, 5-hexylnorbornene (HexNB) and 5-decylnorbornene (DecNB) are known to have low Dk and Df due to their hydrophobic nature these films exhibit high CTE (>200 ppm/K) and low T_{g}. See, for example, JP 2016037577A and JP 2012121956A.

It has also been reported in the literature that certain of the polymers, such as for example, fluorinated poly-ethylene, poly-ethylene and poly-styrene feature low Dk/Df but all of such polymers are unsuitable as organic insulating materials as they exhibit very low glass transition temperatures, which can be much lower than 150° C. Further, it has also been reported in the literature that generally low CTE and high T_{g} polymers can be generated when certain substituted norbornenes substituted with polar groups such as ester or alcohol groups are incorporated. However, incorporation of such groups will increase both Dk and Df due to their polarizability under an electromagnetic field, particularly at high frequencies. Therefore, such polar group substituted norbornenes are unsuitable in forming insulating materials as contemplated herein. In addition, all of the compositions reported in the art contain a number of ingredients such as acrylates or maleimides or other reactive crosslinkers to generate crosslinked networks, all of which are unsuitable for forming low loss compositions.

Therefore, there is still a need to develop new insulating materials that exhibit not only low dielectric properties but also very high thermal properties.

In addition, there is also a need to develop materials, which can form thermoset films rather than thermoplastic films. That is, the thermosets are generally cross-linked structures, which are more stable to higher temperatures and do not exhibit any thermal mobility unlike thermoplastics.

Accordingly, it is an object of this invention to provide a composition containing a polymer derived from one or more substituted norbornenes and a multifunctional diazirine, which when subjected to suitable thermal or photolytic conditions undergoes crosslinking to form a three-dimensional thermoset network, which can be used as an insulating material having hitherto unattainable properties.

Other objects and further scope of the applicability of the present invention will become apparent from the detailed description that follows.

### SUMMARY OF THE INVENTION

Surprisingly, it has now been found that employing a composition containing a polymer derived from one or more monomers of formula (I) as described herein and at least one multifunctional diazirine of formulae (IIA), (IIB) or (IIC) as described herein, it is now possible to form a three-dimensional thermoset object which provides hitherto unattainable dielectric as well as thermal properties. In another aspect of this invention the composition of this invention further comprises a hydrogenated tackifier as described herein which finds use in forming copper clad laminates, among others. The composition of this invention is also photoimageable and thus can be used in a number of optoelectronic applications, including redistribution layers and millimeter wave radar antenna, among others.

In another aspect of this invention there is also a provided a method of forming films and/or copper clad laminates comprising the composition of this invention.

### BRIEF DESCRIPTION OF THE DRAWINGS

Embodiments in accordance with the present invention are described below with reference to the following accompanying figures and/or images. Where drawings are provided, it will be drawings which are simplified portions of various embodiments of this invention and are provided for illustrative purposes only.

FIG. 1 shows a comparative thermograms obtained from the differential scanning calorimetry (DSC) of a few of the diazirines used to form the compositions of this invention, which are compared with a few of the diazirines known in the art.

FIG. 2A shows a comparative thermograms obtained from the thermomechanical analysis (TMA) of a thermal cured film formed from a composition of this invention, which is compared with an uncured film formed from the polymer alone.

FIG. 2B shows a comparative thermograms obtained from the thermomechanical analysis (TMA) of a photocured film formed from a composition of this invention, which is compared with an uncured film formed from the polymer alone.

FIG. 3A shows a plot of dielectric constant (Dk) measured periodically over a period of 1600 hours at 10 GHz of two films formed from a composition of this invention; one film exposed to 125° C. and stored in air and the other film stored at 85° C. and 85 percent relative humidity.

FIG. 3B shows a plot of low loss (Df) measured periodically over a period of 1600 hours at 10 GHz of two films formed from a composition of this invention; one film exposed to 125° C. and stored in air and the other film stored at 85° C. and 85 percent relative humidity.

FIG. 4 shows a comparative contrast curve of a film formed from the composition of this invention which is compared with a film formed from the composition containing a diazirine reported in the art.

FIG. 5A and FIG. 5B show scanning electron micrograph (SEM) of pillars formed from the imagewise photo exposure of a film formed from the composition of this invention.

FIG. 5C and FIG. 5D show scanning electron micrograph (SEM) of vias formed from the imagewise photo exposure of a film formed from the composition of this invention.

FIG. 5E shows scanning electron micrograph (SEM) of lines formed from the imagewise photo exposure of a film formed from the composition of this invention.

### DETAILED DESCRIPTION OF THE INVENTION

The terms as used herein have the following meanings:

As used herein, the articles “a,” “an,” and “the” include plural referents unless otherwise expressly and unequivocally limited to one referent.

Since all numbers, values and/or expressions referring to quantities of ingredients, reaction conditions, etc., used herein and in the claims appended hereto, are subject to the various uncertainties of measurement encountered in obtaining such values, unless otherwise indicated, all are to be understood as modified in all instances by the term “about.”

Where a numerical range is disclosed herein such range is continuous, inclusive of both the minimum and maximum values of the range as well as every value between such minimum and maximum values. Still further, where a range refers to integers, every integer between the minimum and maximum values of such range is included. In addition, where multiple ranges are provided to describe a feature or characteristic, such ranges can be combined. That is to say that, unless otherwise indicated, all ranges disclosed herein are to be understood to encompass any and all sub-ranges subsumed therein. For example, a stated range of from “1 to 10” should be considered to include any and all sub-ranges between the minimum value of 1 and the maximum value of 10. Exemplary sub-ranges of the range 1 to 10 include, but are not limited to, 1 to 6.1, 3.5 to 7.8, and 5.5 to 10, etc.

As used herein, “hydrocarbyl” refers to a group that contains carbon and hydrogen atoms, non-limiting examples being alkyl, cycloalkyl, aryl, aralkyl, alkaryl, and alkenyl. The term “halohydrocarbyl” refers to a hydrocarbyl group where at least one hydrogen has been replaced by a halogen. The term perhalocarbyl refers to a hydrocarbyl group where all hydrogens have been replaced by a halogen.

As used herein, the expression “alkyl” means a saturated, straight-chain or branched-chain hydrocarbon substituent having the specified number of carbon atoms. Particular alkyl groups are methyl, ethyl, n-propyl, isopropyl, tert-butyl, and so on. Derived expressions such as “alkoxy”, “thioalkyl”, “alkoxyalkyl”, “hydroxyalkyl”, “alkylcarbonyl”, “alkoxycarbonylalkyl”, “alkoxycarbonyl”, “diphenylalkyl”, “phenylalkyl”, “phenylcarboxyalkyl” and “phenoxyalkyl” are to be construed accordingly.

As used herein, the expression “cycloalkyl” includes all of the known cyclic groups. Representative examples of “cycloalkyl” includes without any limitation cyclopropyl, cyclobutyl, cyclopentyl, cyclohexyl, cycloheptyl, cyclooctyl, and the like. Derived expressions such as “cycloalkoxy”, “cycloalkylalkyl”, “cycloalkylaryl”, “cycloalkylcarbonyl” are to be construed accordingly.

As used herein, the expression “perhaloalkyl” represents the alkyl, as defined above, wherein all of the hydrogen atoms in said alkyl group are replaced with halogen atoms selected from fluorine, chlorine, bromine or iodine. Illustrative examples include trifluoromethyl, trichloromethyl, tribromomethyl, triiodomethyl, pentafluorocthyl, pentachloroethyl, pentabromoethyl, pentaiodoethyl, and straight-chained or branched heptafluoropropyl, heptachloropropyl, heptabromopropyl, nonafluorobutyl, nonachlorobutyl, undecafluoropentyl, undecachloropentyl, tridecafluorohexyl, tridecachlorohexyl, and the like. Derived expression, “perhaloalkoxy”, is to be construed accordingly. It should further be noted that certain of the alkyl groups as described herein may partially be fluorinated, that is, only portions of the hydrogen atoms in said alkyl group are replaced with fluorine atoms and shall be construed accordingly.

As used herein the expression “acyl” shall have the same meaning as “alkanoyl”, which can also be represented structurally as “R—CO—,” where R is an “alkyl” as defined herein having the specified number of carbon atoms. Additionally, “alkylcarbonyl” shall mean same as “acyl” as defined herein. Specifically, “(C₁-C₄) acyl” shall mean formyl, acetyl or ethanoyl, propanoyl, n-butanoyl, etc. Derived expressions such as “acyloxy” and “acyloxyalkyl” are to be construed accordingly.

As used herein, the expression “aryl” means substituted or unsubstituted phenyl or naphthyl. Specific examples of substituted phenyl or naphthyl include o-, p-, m-tolyl, 1,2-, 1,3-, 1,4-xylyl, 1-methylnaphthyl, 2-methylnaphthyl, etc. “Substituted phenyl” or “substituted naphthyl” also include any of the possible substituents as further defined herein or one known in the art.

As used herein, the expression “arylalkyl” means that the aryl as defined herein is further attached to alkyl as defined herein. Representative examples include benzyl, phenylethyl, 2-phenylpropyl, 1-naphthylmethyl, 2-naphthylmethyl and the like.

As used herein, the expression “alkenyl” means a non-cyclic, straight or branched hydrocarbon chain having the specified number of carbon atoms and containing at least one carbon-carbon double bond, and includes ethenyl and straight-chained or branched propenyl, butenyl, pentenyl, hexenyl, and the like. Derived expression, “arylalkenyl” and five membered or six membered “heteroarylalkenyl” is to be construed accordingly. Illustrative examples of such derived expressions include furan-2-ethenyl, phenylethenyl, 4-methoxyphenylethenyl, and the like.

As used herein, the expression “heteroaryl” includes all of the known heteroatom containing aromatic radicals. Representative 5-membered heteroaryl radicals include furanyl, thienyl or thiophenyl, pyrrolyl, isopyrrolyl, pyrazolyl, imidazolyl, oxazolyl, thiazolyl, isothiazolyl, and the like. Representative 6-membered heteroaryl radicals include pyridinyl, pyridazinyl, pyrimidinyl, pyrazinyl, triazinyl, and the like radicals. Representative examples of bicyclic heteroaryl radicals include, benzofuranyl, benzothiophenyl, indolyl, quinolinyl, isoquinolinyl, cinnolyl, benzimidazolyl, indazolyl, pyridofuranyl, pyridothienyl, and the like radicals.

As used herein, the expression “heterocycle” includes all of the known reduced heteroatom containing cyclic radicals. Representative 5-membered heterocycle radicals include tetrahydrofuranyl, tetrahydrothiophenyl, pyrrolidinyl, 2-thiazolinyl, tetrahydrothiazolyl, tetrahydrooxazolyl, and the like. Representative 6-membered heterocycle radicals include piperidinyl, piperazinyl, morpholinyl, thiomorpholinyl, and the like. Various other heterocycle radicals include, without limitation, aziridinyl, azepanyl, diazepanyl, diazabicyclo[2.2.1]hept-2-yl, and triazocanyl, and the like.

“Halogen” or “halo” means chloro, fluoro, bromo, and iodo.

In a broad sense, the term “substituted” is contemplated to include all permissible substituents of organic compounds. In a few of the specific embodiments as disclosed herein, the term “substituted” means substituted with one or more substituents independently selected from the group consisting of (C₁-C₆)alkyl, (C₂-C₆)alkenyl, (C₁-C₆)perfluoroalkyl, phenyl, hydroxy, —CO₂H, an ester, an amide, (C₁-C₆)alkoxy, (C₁-C₆)thioalkyl and (C₁-C₆)perfluoroalkoxy. However, any of the other suitable substituents known to one skilled in the art can also be used in these embodiments.

It should be noted that any atom with unsatisfied valences in the text, schemes, examples and tables herein is assumed to have the appropriate number of hydrogen atom(s) to satisfy such valences.

As used herein, the term “self-imageable compositions” will be understood to mean a material that is photodefinable and can thus provide patterned layers and/or structures after direct image-wise exposure of a film formed thereof followed by development of such images in the film using an appropriate developer.

It will be understood that the terms “dielectric” and “insulating” are used interchangeably herein. Thus, reference to an insulating material or layer is inclusive of a dielectric material or layer and vice versa. Further, as used herein, the term “organic electronic device” will be understood to be inclusive of the term “organic semiconductor device” and the several specific implementations of such devices used, for example, in automotive industry.

As used herein, the dielectric constant (Dk) of a material is the ratio of the charge stored in an insulating material placed between two metallic plates to the charge that can be stored when the insulating material is replaced by vacuum or air. It is also called as electric permittivity or simply permittivity. And, at times referred as relative permittivity, because it is measured relatively from the permittivity of free space.

As used herein, “low-loss” is the dissipation factor (Df), which is a measure of loss-rate of energy of a mode of oscillation (mechanical, electrical, or electromechanical) in a dissipative system. It is the reciprocal of quality factor, which represents the “quality” or durability of oscillation.

As used herein, “B-stage” means a material wherein the reaction between the base polymer and the curing agent/hardener is not complete. That is, such “B-staged” material is in a partially cured stage, and generally free of any solvent used to make the composition containing the base polymer and the curing agent/hardener. Generally, when such “B-staged” material is reheated at elevated temperature, the crosslinking is complete, and the material is fully cured.

As used herein, “prepreg” means a material that is pre-impregnated with a polymeric material which can be either a thermoplastic or a thermoset. Generally, a fibrous material such as glass cloth is pre-impregnated with a polymeric material to form prepregs, which is formed by a “B-stage” process and subsequently cured by reheating at elevated temperature.

By the term “derived” is meant that the polymeric repeating units are polymerized (formed) from, for example, polycyclic norbornene-type monomers in accordance with formulae (I) wherein the resulting polymers are formed by 2,3 enchainment of norbornene-type monomers as shown below:

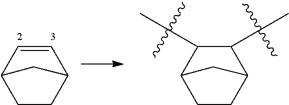

The above polymerization is also known widely as vinyl addition polymerization typically carried out in the presence of organometallic compounds such as organopalladium compounds or organonickel compounds as further described in detail below.

Thus, in accordance with the practice of this invention there is provided a film forming composition comprising:
a) a polycycloolefinic polymer comprising at least one repeat unit represented by formula (IA), said repeat unit is derived from a monomer of formula (I):

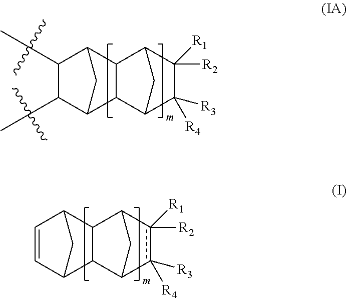

wherein:
[symbol] denotes a place of bonding with another repeat unit;
m is 0, 1 or 2;
[symbol] is a single bond or a double bond;
R₁, R₂, R₃ and R₄ are the same or different and each independently selected from the group consisting of hydrogen, methyl, ethyl, linear or branched (C₃-C₁₆)alkyl, (C₃-C₁₀)cycloalkyl, (C₆-C₁₂)bicycloalkyl, (C₆-C₁₂)aryl and (C₆-C₁₂)aryl(C₁-C₆)alkyl; or one of R₁ and R₂ taken together with one of R₃ and R₄ and the carbon atoms to which they are attached to form a substituted or unsubstituted (C₅-C₁₄)cyclic, (C₅-C₁₄)bicyclic or (C₅-C₁₄)tricyclic ring optionally containing one or more double bonds;
b) a diazirine selected from the group consisting of:
   a bis-diazirine of formula (IIA):

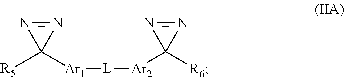

a tris-diazirine of formula (IIB):

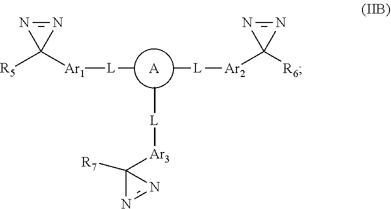

and
a tetrakis-diazirine of formula (IIC):

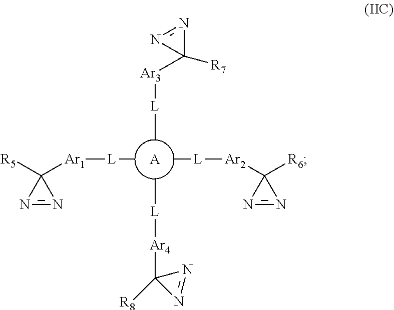

wherein:

L is selected from the group consisting of —O—(C₁-C₁₆)alkylene-O—, —O—(CH₂)₂—O—(C₆-C₁₂)arylene-O—(CH₂)₂—O— and —O—(CH₂)₃—O—(C₆-C₁₂)arylene-O—(CH₂)₃—O—;
A is a trivalent or tetravalent aliphatic, cycloaliphatic or aromatic moiety;
Ar₁, Ar₂, Ar₃ and Ara are the same or different and each independently selected from the group consisting of (C₆-C₁₂)arylene and (C₆-C₁₂) heteroarylene group optionally substituted with a group selected from (C₁-C₄)alkyl, (C₁-C₄)alkoxy, (C₆-C₁₀)aryl, (C₆-C₁₂)aryloxy, (C₆-C₁₂)aryl(C₁-C₄)alkyl and (C₆-C₁₂)aryl(C₁-C₄)alkyloxy; and
R₅, R₆, R₇ and R₅ are the same or different and each independently selected from the group consisting of (C₁-C₆)alkyl, (C₃-C₇)cycloalkyl, (C₆-C₁₂)aryl, perfluoro (C₁-C₆)alkyl and perfluoro (C₃-C₇)cycloalkyl;
wherein a film formed from the composition containing at least one of the diazirine of formula (IIA), (IIB) or (IIC) at an amount of at least about 2.5 parts per 100 parts of the polymer of formula (I) has a dielectric constant (Dk) less than 2.4 at a frequency of 10 GHz, a glass transition temperature greater than 210° C. and a coefficient of thermal expansion (CTE) less than 200 ppm/K.

The polymer as described herein can be prepared by any of the known vinyl addition polymerization in the art. As noted, more than one monomer of formula (I) distinct from each other can be used to form the polymer of this invention. Accordingly, in some embodiments only one monomer of formula (I) is used to form a homopolymer containing repeat units of formula (IA). In some other embodiments, at least two distinctive monomers of formula (I) are employed to form a copolymer containing two respective distinctive repeat units of formula (IA). Again, any desirable amounts of distinctive monomers of formula (I) can be used to form copolymers as described herein. In some embodiments such molar ratios of distinctive monomers of formula (I) can be 10:90, 20:80, 30:70, 40:60, 50:50, and so on. In yet some other embodiments, three distinctive monomers of formula (I) are employed to form a terpolymer to form the composition of this invention. Any of the molar ratios of such three monomers can be employed, such as for example, 10:10:80, 10:20:70, 30:20:50, 40:40:20, 50:40:10, and so on.

In some embodiments, the polymer according to this invention has a repeat units of formula (IA) wherein m is 0 or 1. In some other embodiments, the polymer according to this invention has a repeat units of formula (IA) wherein m is zero. That is, the repeat units of formula (IA) are derived from a monomer of formula (I), which is a derivative of norbornene. Again, one or more distinct monomers of formula (I) can be used to form the polymer of this invention. In some other embodiments the monomer of formula (I) employed is having m equals 1. That is, the monomer employed in this embodiment contains a dimeric norbornene monomer unit, which is also known as tetracyclodecene (TD). However, it should be noted that a combination of monomers of formula (I) having m=0 and m=1 can also be used to form the polymer of this invention. That is, a mixture of norbornene derivatives of formula (I) as described herein can be employed with a suitable tetracyclodecene derivative of formula (I) as described herein can be used to form the polymer of this invention. Again, any suitable amounts of these distinct monomers of formula (I) which will bring about the intended benefit can be employed to form the polymers of this invention. Accordingly, in some embodiments, the polymer according to this invention, encompasses the first repeat unit derived from two distinct monomers of formula (I).

In some embodiments, [symbol] is a single bond. In some other embodiments, R₁, R₂, R₃ and R₄ are the same or different and each independently selected from the group consisting of hydrogen, methyl, ethyl, n-propyl, n-butyl, n-hexyl, n-octyl, n-decyl, cyclopentyl, cyclohexyl, norbornyl, phenyl and phenethyl.

In some other embodiments, one of R₁ and R₂ taken together with one of R₃ and R₄ and the carbon atoms to which they are attached to form a cyclopentyl, cyclohexyl, cycloheptyl, bicycloheptyl, bicyclooctyl, or adamantyl ring.

Again, any of the monomers of formula (I) within the scope of this invention can be employed to form the polymers of this invention. Non-limiting examples of such monomers of formula (I) may be selected from the group consisting of:

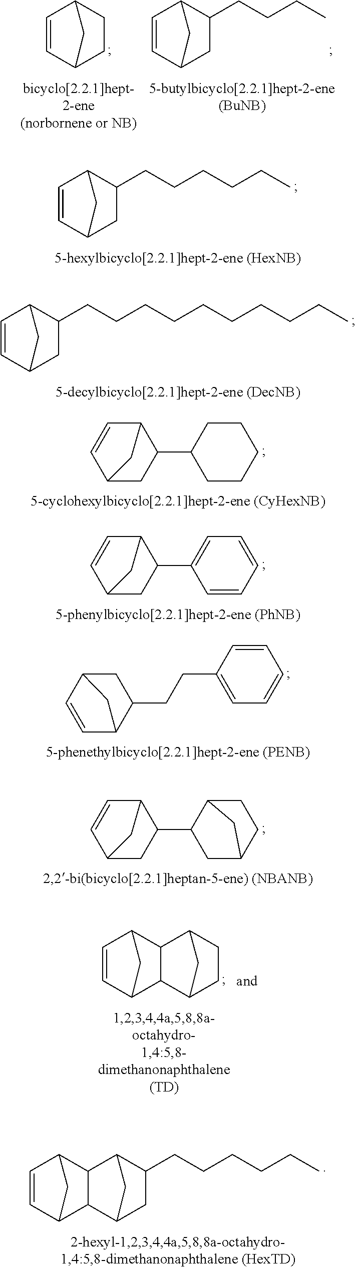

As noted, the polymer employed in the composition of this invention can be a homopolymer, copolymer, terpolymer, and so on. Accordingly, in some embodiments the polymer employed in the composition of this invention is a homopolymer. In some other embodiments the polymer employed in the composition of this invention is a copolymer.

The polymers employed in the composition according to this invention generally exhibit an average molecular weight (M_{w}) of at least about 2,500. In another embodiment, the polymer of this invention has a M_{w} of at least about 3,000, 5,000, 10,000 or 20,000. Advantageously, it has now been found that B-staged films are better formed using low molecular weight polymers as the resulting film made from such composition exhibits good resin flow. In another embodiment, the polymer of this invention has a M_{w} of at least about 100,000. In some other embodiments, the polymer of this invention has a M_{w} of at least about 150,000. In another embodiment, the polymer of this invention has a M_{w} of higher than 200,000, higher than 300,000 and can be higher than 500,000 in some other embodiments. The weight average molecular weight (M_{w}) of the polymer can be determined by any of the known techniques, such as for example, by gel permeation chromatography (GPC) equipped with suitable detector and calibration standards, such as differential refractive index detector calibrated with narrow-distribution polystyrene standards or polybutadiene (PBD) standards. The polymers of this invention typically exhibit polydispersity index (PDI) higher than 3, which is a ratio of weight average molecular weight (M_{w}) to number average molecular weight (Mₙ). In general, the PDI of the polymers of this invention ranges from 3 to 5. In some embodiments the PDI is higher than 3.5, higher than 4, higher than 4.5, or can be higher than 5. However, it should be noted that in some embodiments the PDI can be lower than 3, such as for example, 2.5.

Exemplary non-limiting examples of polymer that can be employed in the composition according to this invention may be enumerated as follows:
a homopolymer of 5-butylbicyclo[2.2.1]hept-2-ene (BuNB);
a homopolymer of 5-hexylbicyclo[2.2.1]hept-2-ene (HexNB);
a homopolymer of 5-decylbicyclo[2.2.1]hept-2-ene (DecNB);
a copolymer of norbornene (NB) and 5-butylbicyclo[2.2.1]hept-2-ene (BuNB);
a copolymer of norbornene (NB) and 5-hexylbicyclo[2.2.1]hept-2-ene (HexNB); and
a copolymer of norbornene (NB) and 5-decylbicyclo[2.2.1]hept-2-ene (DecNB).

Now, turning to diazirines of formulae (IIA), (IIB) and (IIC), several of such diazirines are known in the art. See for example, WO 2022/187932 A1, pertinent portions of which are incorporated herein by reference. In some embodiments the diazirines of formulae (IIA), (IIB) or (IIC) contains:
L selected from the group consisting of —O(CH₂)₂O—, —O(CH₂)₄O—, —O(CH₂)₆O—, —O(CH₂)₈O—, —O(CH₂)₁₀O—, —O(CH₂)₂O—(C₆H4)—O(CH₂)₂O— and —O(CH₂)₂O—(C₆H4)—(C₆H4)—O(CH₂)₂O—.

It should be noted that one or more hydrogen atoms of various “CH₂” connected to oxygen referred to hereinabove can be substituted with an alkyl group. For example, some of the CH₂ can be replaced with CH(C₁-C₆alkyl) or C(C₁-C₆alkyl)₂. All such combinations are within the scope of this invention.

In some other embodiments non-limiting examples of (C₆-C₁₂)arylene moiety include the following:

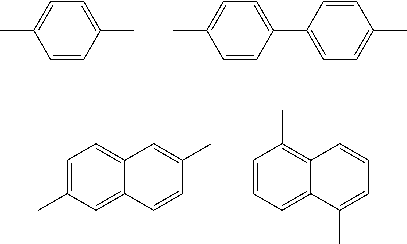

In some other embodiments A is selected from the group consisting of trivalent or tetravalent (C₁-C₅)alkyl, (C₃-C₈)cycloalkyl, (C₆-C₁₂)aryl and (C₆-C₁₂)aryl(C₁-C₄)alkyl. Non-limiting examples of such moieties include the following:

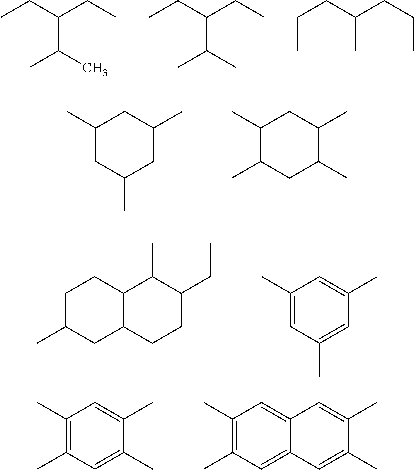

In some other embodiments Ar₁, Ar₂, Ar₃ and Ar₄ are the same or different and each independently selected from the group consisting of phenylene, biphenylene, naphthalene, pyridine and quinoline optionally substituted with a group selected from the group consisting of methyl, ethyl, propyl, butyl, methoxy, ethoxy, propoxy, butoxy, phenyl, phenoxy, phenethyl and phenethoxy; and
R₅, R₆, R₇ and R₅ are the same or different and each independently selected from the group consisting of trifluoromethyl, pentafluoroethyl, heptafluoropropyl and perfluorocyclohexyl.

Non-liming examples within the scope of the diazirine of formula (IA) is selected from the group consisting of:

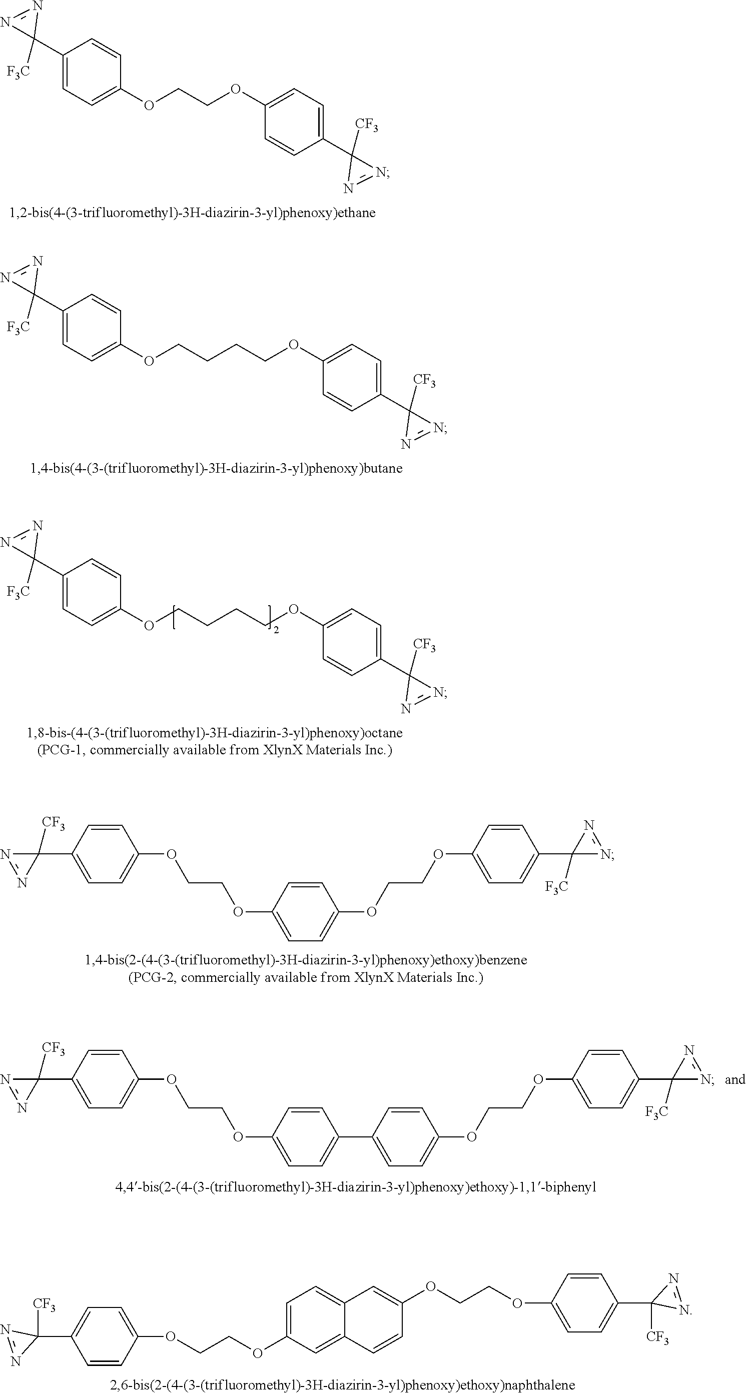

Non-liming examples within the scope of the diazirine of formula (IIB) is selected from the group consisting of:

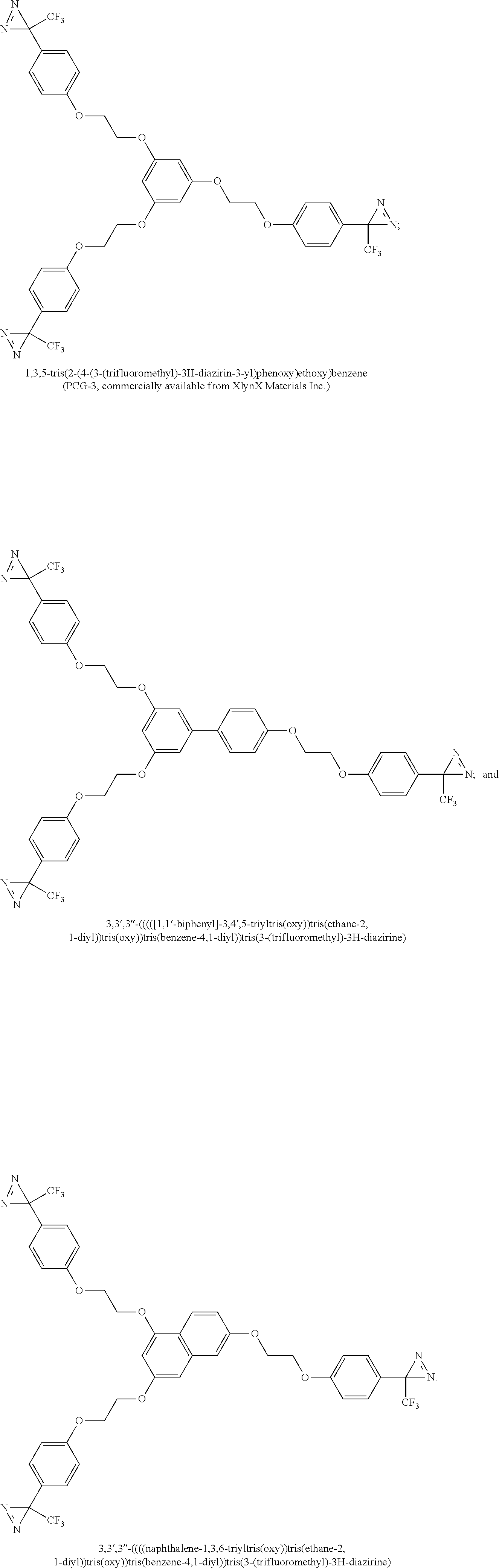 [SMILES: FC(F)(F)C1(c2ccc(OCCOc3cc(OCCOc4ccc(C5(C(F)(F)F)N=N5)cc4)cc(OCCOc4ccc(C5(C(F)(F)F)N=N5)cc4)c3)cc2)N=N1 ; FC(F)(F)C1(c2ccc(OCCOc3ccc(-c4cc(OCCOc5ccc(C6(C(F)(F)F)N=N6)cc5)cc(OCCOc5ccc(C6(C(F)(F)F)N=N6)cc5)c4)cc3)cc2)N=N1 ; FC(F)(F)C1(c2ccc(OCCOc3ccc4c(OCCOc5ccc(C6(C(F)(F)F)N=N6)cc5)cc(OCCOc5ccc(C6(C(F)(F)F)N=N6)cc5)cc4c3)cc2)N=N1]

Non-liming examples within the scope of the diazirine of formula (IIC) is selected from the group consisting of:

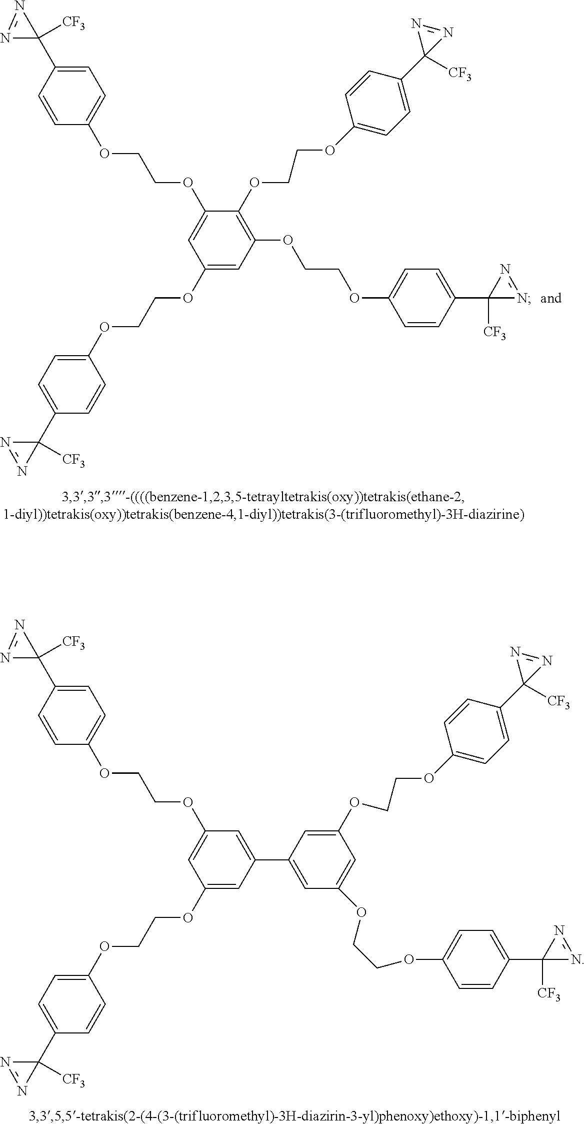 [SMILES: FC(F)(F)C1(c2ccc(OCCOc3cc(OCCOc4ccc(C5(C(F)(F)F)N=N5)cc4)c(OCCOc4ccc(C5(C(F)(F)F)N=N5)cc4)c(OCCOc4ccc(C5(C(F)(F)F)N=N5)cc4)c3)cc2)N=N1 ; FC(F)(F)C1(c2ccc(OCCOc3cc(OCCOc4ccc(C5(C(F)(F)F)N=N5)cc4)cc(-c4cc(OCCOc5ccc(C6(C(F)(F)F)N=N6)cc5)cc(OCCOc5ccc(C6(C(F)(F)F)N=N6)cc5)c4)c3)cc2)N=N1]

Any of the composition within the scope of this invention can be employed to form various thermosets in accordance of this invention. Non-limiting examples of such composition is selected from the group consisting of:
a solution of homopolymer of (5-hexylbicyclo[2.2.1]hept-2-ene) (polyHexNB) and 1,8-bis(4-(3-(trifluoromethyl)-3H-diazirin-3-yl)phenoxy)octane (PCG-1);
a solution of homopolymer of (5-hexylbicyclo[2.2.1]hept-2-ene) (polyHexNB) and 1,4-bis(2-(4-(3-(trifluoromethyl)-3H-diazirin-3-yl)phenoxy)ethoxy)benzene (PCG-2);
a solution of homopolymer of (5-hexylbicyclo[2.2.1]hept-2-ene) (polyHexNB) and 1,3,5-tris(2-(4-(3-(trifluoromethyl)-3H-diazirin-3-yl)phenoxy)ethoxy)benzene (PCG-3);
a solution of copolymer of norbornene and (5-hexylbicyclo[2.2.1]hept-2-ene) (copolyNB/HexNB) and 1,8-bis(4-(3-(trifluoromethyl)-3H-diazirin-3-yl)phenoxy)octane (PCG-1);
a solution of copolymer of norbornene and (5-hexylbicyclo[2.2.1]hept-2-ene) (copolyNB/HexNB) and 1,4-bis(2-(4-(3-(trifluoromethyl)-3H-diazirin-3-yl)phenoxy)ethoxy)benzene (PCG-2); and
a solution of copolymer of norbornene and (5-hexylbicyclo[2.2.1]hept-2-ene) (copolyNB/HexNB) and 1,3,5-tris(2-(4-(3-(trifluoromethyl)-3H-diazirin-3-yl)phenoxy)ethoxy)benzene (PCG-3).

Surprisingly, it has now been observed that employing even amounts of about 2.5 parts of at least one of a diazirine of formulae (IIA), (IIB) or (IIC) per 100 parts of the polymer having the repeat units of formula (IA) it is now possible to form a composition according to this invention which brings about effective crosslinking ability with other materials in forming a composite material having utility in a variety of applications as described hereinbelow.

Accordingly, in some embodiments, the composition according to this invention contains at least one diazirine of formulae (IIA), (IIB) or (IIC) in the amounts of about 2 parts to about 30 parts per 100 parts of the polymer having the repeat units of formula (IA). In yet some other embodiments, the composition according to this invention contains at least one diazirine of formulae (IIA), (IIB) or (IIC) in the amounts of about 2.5 parts to about 25 parts, 5 parts to about 20 parts, 7.5 parts to about 17.5 parts, 10 parts to about 15 parts, per 100 parts of the polymer having the repeat units of formula (IA). It should however be noted that in some embodiments lower than 2 parts of diazirine or higher than 30 parts of diazirine per 100 parts of polymer is employed depending upon the intended use of such composition.

Generally, the composition of this invention are formed as a solution in a suitable organic solvent. Any of the solvents that can solubilize the polymer as well as the diazirine can be employed for this purpose. Suitable solvents include without any limitation, alkane and cycloalkane solvents, such as pentane, hexane, heptane, decalin, cyclohexane and methyl cyclohexane; halogenated alkane solvents such as dichloromethane, chloroform, carbon tetrachloride, ethylchloride, 1,1-dichloroethane, 1,2-dichloroethane, 1-chloropropane, 2-chloropropane, 1-chlorobutane, 2-chlorobutane, 1-chloro-2-methylpropane, and 1-chloropentane; ethers such as THF and diethylether; aromatic solvents such as benzene, xylene, toluene, mesitylene, chlorobenzene, and o-dichlorobenzene; and halocarbon solvents such as Freon® 112; ester solvents such as methyl acetate, ethyl acetate, butyl acetate and amyl acetate; and mixtures in any combination thereof.

Advantageously it has now been found that the composition of this invention can readily be formed into a film by any of the methods known in the art. Even more advantageously the composition of this invention can be formed into films which are photoimageable. Accordingly, the composition of this invention can be employed as photosensitive compositions. Thus, the photosensitive composition embodiments, in accordance with the present invention, are first applied to a desired substrate to form a film. Such a substrate includes any appropriate substrate as is, or may be used for electrical, electronic or optoelectronic devices, for example, a semiconductor substrate, a ceramic substrate, a glass substrate. With regard to said application, any appropriate coating method can be employed, for example spin coating, spraying, doctor blading, meniscus coating, ink jet coating and slot coating.

Next, the coated substrate is heated to facilitate the removal of residual casting solvent, for example to a temperature from 70° C. to 100° C. for from 1 to 10 minutes, although other appropriate temperatures and times can be used. After the heating, the film is generally imagewise exposed to an appropriate wavelength of actinic radiation, wavelength is generally selected based on the diazirine of formulae (IIA), (IIB) or (IIC) employed in the composition as described herein. However, generally such appropriate wavelength is from 200 to 700 nm. Optionally a suitable photoactive compound and/or photosensitizer can additionally be employed to sensitize the composition to certain wavelength. It will be understood that the phrase “imagewise exposure” means exposing through a masking element to provide for a resulting pattern of exposed and unexposed portion of the film.

After an imagewise exposure of the film formed from the photosensitive composition embodiments in accordance with the present invention, a development process is employed. As the composition of this invention undergoes crosslinking upon actinic radiation the exposed regions are crosslinked and become fixed. That is, the composition of this invention is used as a negative tone compositions where a development process removes only unexposed portions of the film thus leaving a negative image of the masking layer in the film. For some embodiments, a post exposure bake can be employed prior to the aforementioned development process.

Suitable developers for negative tone compositions include organic solvents such as 2-heptanone, cyclohexanone, toluene, xylene, ethyl benzene, mesitylene and butyl acetate, and mixtures in any combination thereof. After such development step the substrate is dried with a stream of nitrogen to reveal the images, which can be examined by various methods including for example optical microscopy, scanning electron microscopy, among others. Excellent resolution of images were observed. In some embodiments the resolution of images is as low as 1 μm. In some other embodiments the resolution of images ranges from 1 μm to 5 μm.

As noted, the compositions of this invention can also be cured by subjecting the films to suitable temperature. Any of the temperature conditions that will thermally activate the diazirines of formulae (IIA), (IIB) or (IIC) can be employed to cure the composition of this invention. Surprisingly, it has now been found that lower temperatures, such as for example, a temperature in the range of about 80° C. to 150° C. is sufficient to cure the composition of this invention to form a variety of thermoset articles. Accordingly, in some embodiments the films formed as described above are subjected to a temperature of about 80° C. for about one hour or more maybe sufficient to cure the compositions of this invention. In yet some other embodiments the films formed as described above are subjected to a temperature in the range of about 100° C. to 140° C. for about one hour or less maybe sufficient to cure the compositions of this invention. In yet some other embodiments the films formed as described above are subjected to a temperature in the range of about 120° C. to 130° C. for about 30 minutes to about one hour maybe sufficient to cure the compositions of this invention.

The films thus formed is used to produce materials having hitherto unattainable properties, such as for example, extremely low coefficient of thermal expansion (CTE), which can be as low as 200 ppm/° K, below 150 ppm/° K, or lower than 50 ppm/° K, especially when a composite material is formed for example with a glass cloth. That is, composite materials generally feature lower CTE than the film itself. The films formed from the composition of this invention also exhibit extremely low dielectric constant as well as low loss properties. For example, dielectric constant (Dk) of the films formed from the composition of this invention can be as low as 2.3 or lower and can be in the range of from about 2.2 to about 2.6 at a frequency of GHz. The low loss (Df) of the film can be lower than 0.0015, and may range from about 0.0006 to 0.0034. In addition, the film formed from the composition of this invention exhibits extremely high glass transition temperature (T_{g}), which can be higher than 200° C., and generally ranges from about 150° C. to 300° C. Even more importantly, the film formed from the composition of this invention readily binds with other materials as illustrated further below. Accordingly, in some embodiments the film formed from the composition of this invention has dielectric constant (Dk) of 2.26 to 2.57 at a frequency of 10 GHz, a glass transition temperature from about 220° C. to about 280° C. and a coefficient of thermal expansion (CTE) from about 100 ppm/K to about 200 ppm/K.

It should be further noted that the composition of this invention contains only the polymer having the repeat units of formula (IA) and at least one of a diazirine of formulae (IIA), (IIB) or (IIC), which provides excellent properties as described herein. More importantly, many of the compositions available in the art contain various components such as acrylates or maleimide crosslinkers, other compounds containing olefinic groups, reactive crosslinkers, all of which are reactive to oxygen environment. Accordingly, the composition of this invention offers unique advantages in that low reactivity to oxygen environment can be maintained especially during high temperature fabrication conditions as commonly observed in the low loss applications.

In a further aspect of this invention, the composition according to this invention further comprises one or more tackifiers. Generally, the purpose of the tackifier is not only to increase the adhesiveness of the composition but also to improve the softness of the composition especially while fabricating at temperatures higher than 130° C. so that the composition may have some flow to impregnate the glass cloth or to fuse with other layers of the device. As noted, the composition of this invention can generally be crosslinked at a temperature of about 130° C., and it is beneficial to keep the composition soft at this temperature. Accordingly, any of the tackifiers that would bring about this benefit can be used in the compositions of this invention. In addition, the amount of tackifier used can also vary depending on the intended use. Generally, such amounts can range from about 5 to 30 parts per hundred parts of polymer (pphr), 8 to 25 pphr, 10 to 20 pphr, and so on. It should be noted that a combination of two or more tackifiers can also be used in the composition of this invention. In such situations the combined amount can be adjusted in order to provide the intended benefit. Advantageously it has now been found that a suitable tackifier that can be employed in the composition of this invention is a fully hydrogenated tackifier.

Accordingly, any of the known fully hydrogenated tackifier can be employed in this aspect of the composition of this invention. In some embodiments such an example of hydrogenated tackifier is a fully hydrogenated hydrocarbon resin. Advantageously it has now been observed that there is no need to employ commonly used butadiene rubbers and/or styrene butadiene rubbers which contain double bonds, which may be detrimental in certain situations and may also be unstable due to the reactivity of the double bonds present therein. Most of the prior art compositions used in similar application contain such olefinic groups, which are used in combination with acrylate or maleimide type crosslinkers, all of which create more reactive environment and thus not stable. None of such reactive tackifiers and/or crosslinkers are employed in the composition of this invention thus providing many advantages.

Non-limiting examples of such tackifiers that are suitable in the composition of this invention is selected from the group consisting of hydrogenated dicyclopentadiene polymer, hydrogenated ethylene-propylene-dicyclopentadiene terpolymer,

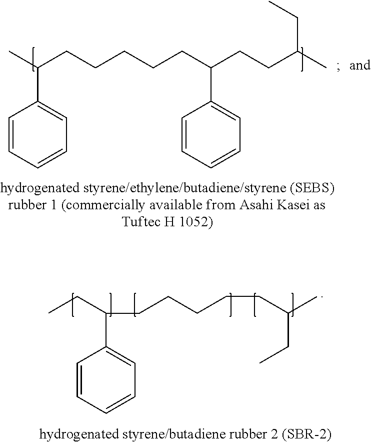

Advantageously, it has now been found that the compositions containing aforementioned tackifiers are useful in forming a number of composites containing various materials including a metal foil and a glass fabric. Accordingly, in some embodiments there is provided a glass cloth composite impregnated with a composition of this invention which is cured either thermally or by exposing to suitable actinic radiation as described herein. These composites can be prepared on a metal foil such as copper foil. Thus, in some embodiments there is further provided a copper-clad laminates comprising the composition of this invention.

In general, the composition in accordance with the present invention encompass the above described one or more of a polymer containing one or more repeat units of formula (IA) and at least one diazirine if formulae (IIA), (IIB) or (IIC), optionally containing a hydrogenated tackifier, as it will be seen below, various composition embodiments are selected to provide properties to such embodiments that are appropriate and desirable for the use for which such embodiments are directed, thus such embodiments are tailorable to a variety of specific applications. Accordingly, in some embodiments the composition of this invention contains a homopolymer or copolymer containing respective repeat units of formula (IA) and at least one diazirine of formulae (IIA), (IIB) or (IIC), optionally a hydrogenated tackifier.

For example, as already discussed above, by employing proper combination of a polymer containing repeat units of formula (IA) and a diazirine as described herein it is now possible to tailor a composition having the desirable low dielectric properties and thermo-mechanical properties, among other properties. In addition, it may be desirable to include other polymeric or monomeric materials which are compatible to provide desirable low-loss and low dielectric properties depending upon the end use application as further discussed in detail below.

Even more advantageously it has now been found that employing suitable amounts of a diazirine as described herein it is now possible to form crosslink structures within the polymeric framework. That is, crosslinks can occur intra-molecular (i.e., between two cross-linkable sites on the same polymer chain). Statistically, this can happen and all such combinations are part of this invention. By forming such inter-molecular or intramolecular crosslinks the polymeric networks formed from the composition of this invention provide hitherto unobtainable properties. This may include, for example, improved thermal properties. That is, much higher glass transition temperatures than observed for non-crosslinked polymers of similar composition. In addition, such crosslinked polymers are more stable at higher temperatures, which can be higher than 350° C. High temperature stability can also be measured by well-known thermogravimetric analysis (TGA) methods known in the art. One such measurement includes a temperature at which the polymer loses five percent of its weight (T_{d5}). As will be seen below by specific examples that follow the T_{d5} of the polymers formed from the composition of this invention can generally be in the range from about 270° C. to about 320° C. or higher. In some embodiments, the T_{d5} of the polymers formed from the composition of this invention is in the range from about 280° C. to about 300° C.

It should be noted that the crosslinked polymers formed from the composition of this invention form thermosets thus offering additional advantages especially in certain applications where thermoplastics are not desirable. For example, any of the applications where higher temperatures are involved the thermoplastic polymers become less desirable as such polymeric materials may flow and are not suitable for such high temperature applications. Such applications include millimeter wave radar antennas as contemplated herein, among other applications.

The compositions in accordance with the present invention may further contain optional additives as may be useful for the purpose of improving properties of both the composition and the resulting object made therefrom. Such optional additives for example may include anti-oxidants and synergists. Any of the anti-oxidants that would bring about the intended benefit can be used in the compositions of this invention. Non-limiting examples of such antioxidants include pentaerythritol tetrakis(3-(3,5-di-tert-butyl-4-hydroxyphenyl) propionate) (IRGANOX™ 1010 from BASF), 3,5-bis(1,1-dimethylethyl)-4-hydroxy-octadecyl ester benzenepropanoic acid (IRGANOX™ 1076 from BASF) and thiodiethylene bis[3-(3,5-di-tert.-butyl-4-hydroxy-phenyl) propionate] (IRGANOX™ 1035 from BASF). Non-limiting examples of such synergists include certain of the secondary antioxidants which may provide additional benefits such as for example prevention of autoxidation and thereby degradation of the composition of this invention and extending the performance of primary antioxidants, among other benefits. Examples of such synergists include, tris(2,4-ditert-butylphenyl) phosphite, commercially available as IRGAFOS 168 from BASF, various diamine synergists such as for example, N,N′-di-2-naphthyl-1,4-phenylenediamine, among others. Another synergist which may be suitable as an additive in the composition of this include certain diesters, such as for example, didodecyl 3,3′-thiodipropionate, whose structure is shown below:

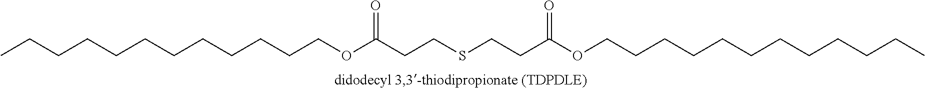 [SMILES: CCCCCCCCCCCCOC(=O)CCSCCC(=O)OCCCCCCCCCCCC]

Accordingly, the composition of this invention can be formed into films simply by following any of the known film casting techniques, including, for example, doctor blading, drum rolling, extrusion and/or spin coating, among other known methods. Accordingly, there is further provided a film formed from the composition of this invention. For example, any of the composition of this invention can be doctor-bladed onto a suitable substrate such as, for example, a glass plate. The coated plate is then heated to suitable temperature in an inert atmosphere to remove any residual solvent. Such temperatures can range from about 80° C. to 150° C. or 120° C. to 140° C. Suitable inert atmosphere can be nitrogen or argon. The heating at these temperatures for sufficient length of time will remove all of the residual solvent, for example a time interval of about 3 minutes to about 60 minutes. This initial stage of film forming is generally called as B-staged films. Under these conditions the film is still soluble in a suitable solvent such as, for example THF, and is not fully crosslinked. The B-staged films are then further heated to higher temperature, which can range from about 150° C. to 220° C. or 160° C. to 190° C. or 130° C. to 160° C. in an inert atmosphere for sufficient length of time in order to affect the crosslinking of the film. Generally, such heating is carried out for about 90 minutes to 150 minutes to ensure full crosslinking of the composition, which is confirmed by insolubility of the polymer film.

As noted, the film thus formed in accordance with this invention exhibits unusually low dielectric constant, low loss, low coefficient of thermal expansion (CTE) and high glass transition temperature. In some embodiments the film formed according to this invention exhibits a dielectric constant (Dk) less than 3, less than 2.8, less than 2.6, less than 2.5, less than 2.4, less than 2.3 at a frequency of 10 GHz, a glass transition temperature (T_{g}) in the range from about 150° C. to 280° C. or higher. In some other embodiments the T_{g} can be higher than 150° C., higher than 200° C., higher than 250° C. In yet some other embodiments the film according to this invention exhibits coefficient of thermal expansion (CTE) in the range of from about 80 ppm/K to 120 ppm/K, and a CTE less than 50 ppm/K when composited with glass cloth.

The film according to this invention can be formed from any of the specific embodiment of the composition as enumerated hereinabove. In a further aspect of this invention there is also provided a film formed from the polymer of this invention.

In a further embodiment, the film according to this invention exhibits a dielectric constant (Dk) less than 3 at a frequency of 10 GHz, a glass transition temperature higher than 150° C. and a coefficient of thermal expansion (CTE) less than 180 ppm/K.

It should be noted that the composition of this invention can be formed into any shape or form and not particularly limited to film. Accordingly, in some embodiments the composition of this invention can be formed into a sheet. The thickness of the sheet is not particularly limited, but when the application as a dielectric material is considered, the thickness is, for example, 0.01 to 0.5 mm. In some other embodiments the thickness is from about 0.02 to 0.2 mm. The sheet so formed generally does not substantially flow at room temperature (25° C.). The sheet may be provided on an arbitrary carrier layer or may be provided alone. Examples of the carrier layer include a polyimide film or a glass sheet. Any other known peelable film substrates may be used as the carrier layer.

As described above, the film/sheet formed in accordance of this invention has good dielectric properties. In quantitative terms, the relative permittivity, i.e., the dielectric constant (Dk) of the film/sheet at a frequency of 10 GHz is from about 2.2 to 2.38. The dielectric loss tangent at a frequency of 10 GHz is from about 0.0003 to 0.005, and in some other embodiments it is from about 0.0004 to 0.003. As a result, the composition of the present invention finds applications in a variety of devices where such low dielectric materials are needed, such as for example the millimeter wave radar to an antenna, among others. See for example, JP 2018-109090 and JP 2003-216823. An antenna is usually composed of an insulator and a conductor layer (for example, copper foil). The composition or sheet of the present invention can be used as a part or the whole of the insulator. The antenna using the composition or the sheet of the present invention as a part or the whole of the insulator has good high-frequency characteristics and reliability (durability).

The conductor layer in the antenna is formed of, for example, a metal having desirable conductivity. A circuit is formed on the conductor layer by using a known circuit processing method. Conductors forming the conductor layer include various metals having conductivity, such as gold, silver, copper, iron, nickel, aluminum, or alloy metals thereof. As a method for forming the conductor layer, a known method can be used. Examples include vapor deposition, electroless plating, and electrolytic plating. Alternatively, the metal foil (for example, copper foil) may be pressure-bonded by thermocompression bonding. The metal foil constituting the conductor layer is generally a metal foil used for electrical connection. In addition to the copper foil, various metal foils such as gold, silver, nickel and aluminum can be used. It may also comprise an alloy foil substantially (for example, 98 wt % or more) composed of these metals. Among these metal foils, a copper foil is commonly used. The copper foil may be either a rolled copper foil or an electrolytic copper foil.

It should be noted that the composition of this invention can also be used as a low molecular weight varnish-type material for certain applications. In such applications suitable amount of the low molecular weight polymer is dissolved in a desirable solvent to form the composition of this invention.

While making a sheet and to secure the flatness of the sheet and suppressing unintended shrinkage, various heating methods known to make sheet materials may be employed. For example, it is possible to heat at a relatively low temperature at first, and then gradually raise the temperature. In order to ensure flatness or the like, heating may be performed by pressurizing with a flat plate (glass plate) or the like before heating and/or by pressurizing with a flat plate. The pressure used for such pressurization may be, for example, 0.1 to 8 MPa, and in some other embodiments it may range from about 0.3 to 5 MPa.

In yet another aspect of this invention there is further provided a method of forming a film for the fabrication of a variety of optoelectronic and/or automotive device comprising:
forming a homogeneous solution comprising a polymer containing repeat units of formula (IA) and at least one of a diazirine of formulae (IIA) or (IIB) or (IIC); and optionally a hydrogenated tackifier as described herein;
coating a suitable substrate with the composition or pouring the composition onto a suitable substrate to form a film; and
heating the film to a suitable temperature to form crosslinked thermoset; or
exposing the film to suitable actinic radiation to form crosslinked thermoset.

The coating of the desired substrate to form a film with the composition of this invention can be performed by any of the coating procedures as described herein and/or known to one skilled in the art, such as by doctor blading or spin coating. Other suitable coating methods include without any limitation spraying, doctor blading, meniscus coating, ink jet coating and slot coating. The mixture can also be poured onto a substrate to form a film. Suitable substrate includes any appropriate substrate as is, or may be used for electrical, electronic or optoelectronic devices, for example, a semiconductor substrate, a ceramic substrate, a glass substrate.

Next, the coated substrate is baked, i.e., heated to facilitate the crosslinking of the polymer to form a thermoset, for example to a temperature from 50° C. to 150° C. for about 1 to 180 minutes, although other appropriate temperatures and times can be used. In some embodiments the substrate is baked at a temperature of from about 100° C. to about 120° C. for 120 minutes to 180 minutes. In some other embodiments the substrate is baked at a temperature of from about 110° C. to about 150° C. for 60 minutes to 120 minutes.

The films thus formed are then evaluated for their electrical properties using any of the methods known in the art. For example, the dielectric constant (Dk) or permittivity and dielectric loss tangent at a frequency of 10 GHz was measured using a device for measuring the permittivity by the cavity resonator method (manufactured by AET, conforming to JIS C 2565 standard). The coefficient of thermal expansion (CTE) was measured using a thermomechanical analysis apparatus in accordance with a measurement sample size of 4 mm (width)×40 mm (Length)×0.1 mm (thickness), a measurement temperature range of 30˜350° C., and a temperature rising rate of 5° C./min. The coefficient of linear expansion from 50° C. to 100° C. was adopted as the coefficient of linear expansion. Generally, the films formed according to this invention exhibit excellent dielectric properties and can be tailored to desirable dielectric properties as described herein.

Accordingly, in some of the embodiments of this invention there is also provided a film or sheet obtained by the mass polymerization of the composition as described herein. In another embodiment there is also provided an electronic device comprising the film/sheet of this invention as described herein.

The following examples are detailed descriptions of methods of preparation and use of certain compounds/monomers, polymers and compositions of the present invention. The detailed preparations fall within the scope of, and serve to exemplify, the more generally described methods of preparation set forth above. The examples are presented for illustrative purposes only, and are not intended as a restriction on the scope of the invention.

### EXAMPLES (GENERAL)

The following abbreviations have been used hereinbefore and hereafter in describing some of the compounds, instruments and/or methods employed to illustrate certain of the embodiments of this invention:
Poly(HexNB)—a homopolymer of HexNB-5-hexylbicyclo[2.2.1]hept-2-ene; Poly(NB/HexNB)—a copolymer of norbornene (NB) and HexNB of 80/20 molar ration; PCG-1—1,8-bis(4-(3-(trifluoromethyl)-3H-diazirin-3-yl)phenoxy)octane; PCG-2—1,4-bis(2-(4-(3-(trifluoromethyl)-3H-diazirin-3-yl)phenoxy)ethoxy)benzene; PCG-3—1,3,5-tris(2-(4-(3-(trifluoromethyl)-3H-diazirin-3-yl)phenoxy)ethoxy)benzene; Comp. PCG-A—3,3′-((oxybis(methylene))bis(4,1-phenylene))bis(3-(trifluoromethyl)-3H-diazirine); Comp. PCG-B—3,3′-((perfluoropropane-2,2-diyl)bis(4,1-phenylene))bis(3-(trifluoromethyl)-3H-diazirine); Tufftec H-1052 tackifier—fully hydrogenated styrene/butadiene rubber; Irganox-1076—3,5-bis(1,1-dimethylethyl)-4-hydroxy-octadecyl ester benzenepropanoic acid: Irgafos-168—tris(2,4-ditert-butylphenyl)phosphite; THF—tetrahydrofuran; TFT—trifluoro toluene; DSC—differential scanning calorimetry; TGA—thermogravimetric analysis; TMA—thermomechanical analysis; DMA—dynamic mechanical analysis; GPC—gel permeation chromatography; M_{w}—weight average molecular weight; Mₙ—number average molecular weight; PDI—polydispersity index; pphr—parts per hundred parts resin, the resin refers to the polymer employed in the composition.

Various polymers as used herein can be readily prepared following the procedures as described in U.S. Pat. No. 7,612,146, pertinent portions of which are incorporated herein by reference.

### Example 1

### Thermal Reactivity of Various Diazirines

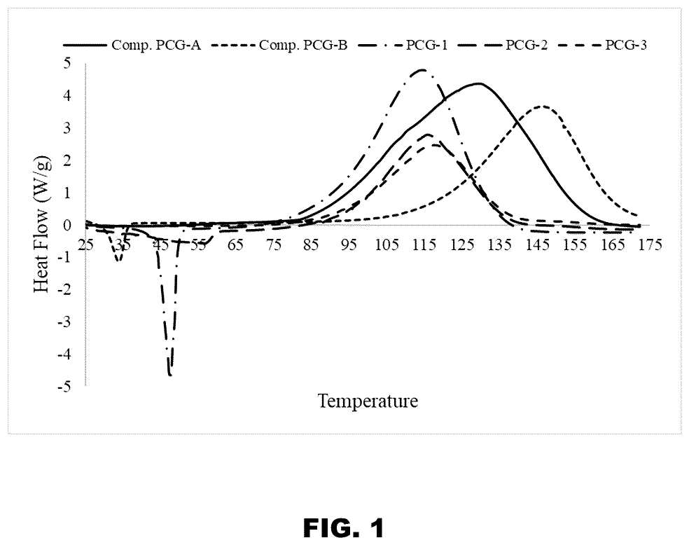

DSC was used to determine the thermal characteristics of various diazirines in accordance with this invention. The diazirines also designated as photo carbene generators, PCG-1, PCG-2 and PCG-3 were tested for their thermal behavior in the temperature range of 30-200° C. For comparison, the diazirines reported in the prior art, Comp. PCG-A, and Comp. PCG-B, were also tested by DSC in the same temperature range. The exotherms generated were calculated as the integrated area of the heat flow (Watts/g) vs. temperature plots. FIG. 1 shows the DSC plots of various diazirines tested and Table 1 lists the exotherms generated (enthalpy of diazirine thermal decomposition) per gram of diazirine, the temperature at which the exotherm peaked and the temperature range in which these diazirine cross-linkers are thermally activated so that C—H insertion reaction can occur to cross-link suitable polymers to generate thermosets. In some cases, the melting points of the diazirines were roughly estimated by the appearance of an endothermic event. It is clear from FIG. 1 and the data presented in Table 1 that PCG-1, PCG-2 and PCG-3 demonstrate the ability to be activated at lower temperatures (i.e., less than 100° C.) thereby capable of higher thermal reactivity towards polymers containing C—H or other suitable bonds for carbene insertions. Whereas Comp. PCG-B needed higher temperature to be activated (low thermal reactivity) and Comp. PCG-A had intermediate thermal reactivity between PCG-B and other diazirines made in accordance of this invention.

TABLE 1

| | | Exotherm | Active | Melting |
|---|---|---|---|---|
| | Exotherm | Peak | Range | Point |
| Diazirine | (J/g) | (° C.) | (° C.) | (° C.) |
| PCG-1 | 728 | 115 | 75-140 | 45 |
| PCG-2 | 482 | 117 | 85-140 | — |
| PCG-3 | 424 | 119 | 85-140 | — |
| Comp. PCG-A | 1010 | 130 | 80-160 | — |
| Comp. PCG-B | 602 | 147 | 100-175 | 35 |

The comparative bis-diazirines used in Example 1, Comp. PCG-A and Comp. PCG-B, whose structures are shown below, are known in the art, see for example U.S. Pat. No. 9,938,241 B2 discloses Comp. PCG-A and WO 2020/215144 A1 discloses Comp. PCG-B.

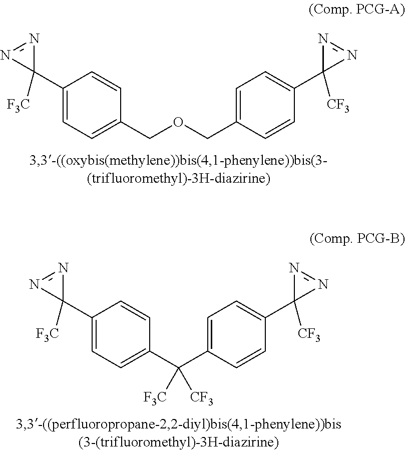 [SMILES: FC(F)(F)C1(c2ccc(COCc3ccc(C4(C(F)(F)F)N=N4)cc3)cc2)N=N1 ; FC(F)(F)C1(c2ccc(C(c3ccc(C4(C(F)(F)F)N=N4)cc3)(C(F)(F)F)C(F)(F)F)cc2)N=N1]

### Example 2

### Photo and Thermal Curing of the Compositions

A homopolymer, poly(HexNB) (having a M_{w} of 193,500, Mₙ of 75,300 and PDI of 2.6), was dissolved in decane to prepare 20 wt. % solution. Bis-diazirine, PCG-1, at levels ranging from 2.5 pphr to 15 pphr was added to form the compositions in accordance with this invention as listed in Table 2. Films were cast on glass substrates by doctor-blading. Any residual solvent was removed by heating the coated glass substrates to 70-80° C. in an oven under nitrogen atmosphere. The films thus generated had thicknesses of about 40-180 μm and were soluble in tetrahydrofuran (THF or decane) indicating that the bis-diazirines contained in the composition did not crosslink the polymer under the conditions used for the removal of solvent. The films were thermally cured by heating to 130° C., a temperature that was sufficient to activate the diazirines according to the DSC plots shown in FIG. 1 and the active temperature ranges as listed in Table 1. The films were also photo-cured by exposing to 365 nm (i-line) irradiation at 1500 mJ/cm² dose. Under these conditions the films were fully crosslinked as demonstrated by unsuccessful attempts to dissolve the cured films in decane or THF for 1 hour under sonication. The homopolymer used in this Example 2 is readily soluble in THF as well as in decane. Thus, Example 2 illustrates that the films made using the compositions of this invention are capable of forming stable crosslinkable films when subjected to either photo or thermal cure conditions as demonstrated by the results shown in Table 2. Further, Table 2 also lists the results obtained by a film formed from the solution containing only poly(HexNB), which when exposed to either actinic radiation or similar thermal conditions did not result in any crosslinked film as the film completely dissolved in decane. It is further evident that 2.5 pphr of a diazirine is sufficient to form compositions which result in curable films as listed in Table 2.

TABLE 2

| | Diazirine | Cure | |
|---|---|---|---|
| Example No. | Loading | Condition | Solubility |
| Comparative | none | 130° C./30 min | Yes (decane) |
| Example 1A1 | | | |
| Comparative | none | 1500 mJ/cm² | Yes (decane) |
| Example 1A2 | | | |
| Example 2C1 | 2.5 pphr | 130° C./60 min | No (THF) |
| Example 2C2 | 2.5 pphr | 1500 mJ/cm² | No (THF) |
| Example 2D1 | 5.0 pphr | 130° C./60 min | No (THF) |
| Example 2D2 | 5.0 pphr | 1500 mJ/cm² | No (THF) |
| Example 2E1 | 10 pphr | 130° C./60 min | No (THF) |
| Example 2E2 | 10 pphr | 1500 mJ/cm² | No (THF) |
| Example 2F1 | 15 pphr | 130° C./60 min | No (THF) |
| Example 2F2 | 15 pphr | 1500 mJ/cm² | No (THF) |

### Example 3

### Thermomechanical Analysis of Cured Films (TMA and Instron)

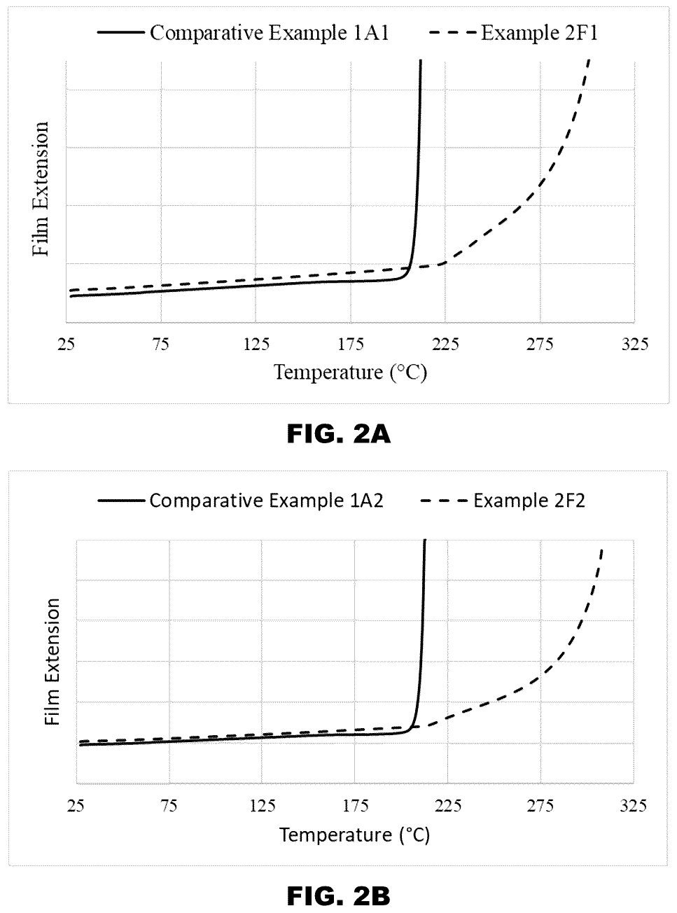

The photo and thermally cured films from Example 2 containing 15 pphr of PCG-1 were analyzed by TMA to determine the thermomechanical properties. FIG. 2A (thermally cured) and FIG. 2B (photo cured) shows the respective thermomechanical characteristics of the film formed from the composition of this invention, which is compared with a film which contained no PCG-1. FIGS. 2A and 2B clearly demonstrate that the cross-linking reactions had occurred in the presence of PCG-1 bis-diazirine cross-linker since a significant change in thermo-mechanical behavior accompanying an increase in glass transition temperatures (T_{g}) were observed. Maximum tensile strength and Young's modulus were also determined for the cured films using Instron. The results are summarized in Table 3. It is evident from the data presented in Table 3 that higher T_{g} and tensile strength can be obtained for the crosslinked films.

TABLE 3

| | | | | | Tensile | Young's |
|---|---|---|---|---|---|---|
| | Cure | CTE | T_{g} | T_{d5} | Strength | Modulus |
| Films Used | Conditions | (ppm/K) | (° C.) | (° C.) | (MPa) | (GPa) |
| No PCG-1 | Thermal | 196 | 206 | 348 | 14 | 0.7 |
| PCG-1, 15 pphr | Thermal | 199 | 221, 288 | 338 | 18 | 0.6 |
| PCG-1, 15 pphr | Photo | 183 | 213, 287 | 334 | n.m. | n.m. |

T_{d5}—temperature at which 5 wt. % loss of material occurs; n.m.—not measured.

### Example 4

### Dielectric Properties of Thermally Cured Films

A homopolymer, poly(HexNB) (having a M_{w} of 147,100; Mₙ of 54,800; and PDI of 2.7), was dissolved in mesitylene to prepare 20 wt. % solution. Various amounts of PCG-1 was added to form the compositions in accordance of this invention as listed in Table 4. For comparative purposes, comparative compositions were also made using Comp. PCG-A and Comp. PCG-2. Films were cast by doctor-blading on glass substrates and heated to 70° C. for 20 minutes on a hot-plate in air to remove any residual solvent. The films thus obtained having a thickness of about 100-140 μm were cured by heating to 150° C. in an oven under nitrogen atmosphere for 1 hour. At which time the films became insoluble in THF indicating that the films were fully cured. Dielectric Constant (Dk) and Dielectric Dissipation Factor (Df) or tan 8 were measured at 10 GHz. The same measurements were made for the films formed from the comparative compositions containing no bis-diazirines, Comp. PCG-A and Comp. PCG-B. The results are summarized in Table 4. The films formed from the compositions of this invention generally exhibited slightly higher Dk and Df than the film formed from a composition containing no bis-diazirine. Similarly, the film formed from a composition containing Comp. PCG-B exhibited slightly lower Dk and Df than the film formed from the composition of this invention. However, the film formed from the composition containing Comp. PCG-A exhibited higher Dk and Df than the film formed from the composition of this invention. Nevertheless, the data summarized in Table 4 indicates that the compositions of this invention are capable of producing films having low dielectric constants (2.3-2.6 at 10 GHz) and low dielectric dissipation factors (0.0009-0.0034) thus suitable for various low loss applications such as high-speed laminates and other automotive applications such as mmWave Radar Antenna.

TABLE 4

| | Bis-diazirine | Cure | Dk at 10 | Df at 10 |
|---|---|---|---|---|
| Bis-diazirine | loading | Temperature | GHz | GHz |
| none | — | 130° C. | 2.17 | 0.0003 |
| Comp. PCG-A | 10 pphr | 150° C. | 2.41 | 0.0029 |
| Comp. PCG-A | 20 pphr | 150° C. | 2.49 | 0.0040 |
| Comp. PCG-B | 20 pphr | 130° C. | 2.22 | 0.0016 |
| PCG-1 | 2.5 pphr | 130° C. | 2.34 | 0.0006 |
| PCG-1 | 5.0 pphr | 130° C. | 2.38 | 0.0009 |
| PCG-1 | 10.0 pphr | 130° C. | 2.35 | 0.0014 |
| PCG-1 | 15.0 pphr | 130° C. | 2.36 | 0.0018 |
| PCG-2 | 2.5 pphr | 150° C. | 2.39 | 0.0011 |
| PCG-2 | 5.0 pphr | 150° C. | 2.42 | 0.0016 |
| PCG-2 | 10.0 pphr | 150° C. | 2.52 | 0.0024 |
| PCG-2 | 15.0 pphr | 150° C. | 2.57 | 0.0034 |

### Example 5

### Dielectric Properties of Photo-Cured Films

The films formed in Example 4 (after removing the solvent) were exposed to 365 nm radiation at 1500 mJ/cm² dose instead of the thermal cure.

TABLE 5

| | Bis-diazirine | Exposure | Dk at | Df at |
|---|---|---|---|---|
| Bis-diazirine | loading | (mJ/cm²) | 10 GHz | 10 GHz |
| none | — | 1500 | 2.18 | 0.0003 |
| Comp. PCG-A | 10 pphr | 1500 | 2.33 | 0.0036 |
| Comp. PCG-A | 20 pphr | 1500 | 2.50 | 0.0066 |
| Comp. PCG-B | 10 pphr | 1500 | 2.24 | 0.0012 |
| Comp. PCG-B | 20 pphr | 1500 | 2.21 | 0.0015 |
| PCG-1 | 2.5 pphr | 1500 | 2.34 | 0.0006 |
| PCG-1 | 5.0 pphr | 1500 | 2.31 | 0.0009 |
| PCG-1 | 10.0 pphr | 1500 | 2.30 | 0.0015 |
| PCG-1 | 15.0 pphr | 1500 | 2.38 | 0.0020 |
| PCG-2 | 2.5 pphr | 1500 | 2.44 | 0.0014 |
| PCG-2 | 5.0 pphr | 1500 | 2.41 | 0.0018 |
| PCG-2 | 10.0 pphr | 1500 | 2.51 | 0.0029 |
| PCG-2 | 15.0 pphr | 1500 | 2.36 | 0.0054 |

Dielectric Constant (Dk) and Dielectric Dissipation Factor (Df) or tan 8 were measured at 10 GHz and the data are summarized in Table 5. It is evident from this data that the dielectric measurements of the photo cured films generally follow the behavior of thermally cured films.

### Example 6

### Dielectric Properties of Films at High Frequencies

Applications such as high-speed digital laminate materials for 5G or 6G or automotive applications such as mm Wave Radar Antenna requires equipment operated at high frequencies. The high signal loss at high frequencies is a challenge for the industry. The root-causes are conductive loss arising from the copper surface roughness and the dielectric loss arising from the change in dielectric dissipation factor as the frequency is increased. This Example 6 demonstrate the suitability of the compositions of this invention to form films which exhibit such excellent low loss properties at very high frequencies commonly used in such applications. The films formed in Example 4 was employed in this study. Dielectric constant (Dk) and Dielectric Dissipation Factor (Df) were measured at 35 GHz and 80 GHz. Df remained constant at 0.0016 at this frequency range indicating that the compositions of this invention exhibit excellent low signal loss and low dielectric loss at such high frequency devices.

### Example 7

### Dielectric Properties of Compositions Suitable for Cu-Clad Laminates

Low loss materials are utilized in printed circuit boards as Cu-clad laminates. Such materials are typically B-staged (not cross-linked or only partially cross-linked) first, and then subjected to a cure protocol under which the material may undergo a resin flow before fully cross-linking to form a thermoset. The resin flow may help impregnate any fabric reinforcements or coat any inorganic fillers used in the fabrication of Cu-clad laminates for printed circuit boards. Tackifiers such as butadiene rubbers can be utilized to assist the resin flow as demonstrated in this Example 7.

A homopolymer, poly(HexNB) (having a M_{w} of 193,500; Mₙ of 75,300; and PDI of 2.6) was dissolved in decane to prepare 25 wt. % solution. To this solution were added PCG-1 (15 pphr) and Tufftec H-1052 tackifier (10 pphr). Similarly, a copolymer, poly(NB/HexNB) at 80/20 molar ratio (having a M_{w} of 178,400; Mₙ of 94,850; and PDI of 1.9), was dissolved in toluene to prepare 20 wt. % solution. To this solution were added PCG-1 (15 pphr) and Tufftec H-1052 tackifier (10 pphr). Both of these compositions were doctor bladed separately on glass substrates and heated to 80° C. for 30 minutes in an oven under nitrogen atmosphere to remove any residual solvents to obtain films having a thickness of about 160 μm. These films were thermally cured in an oven under nitrogen atmosphere or photo cured using 365 nm radiation at 2000 mJ/cm² dose. Low Dk, Df NE-glass cloths (from Nittobo, Style #1280, 0.050 mm thickness) were wetted with these compositions and heated to 80° C. for 30 minutes in an oven under nitrogen atmosphere to remove any residual solvent. The thickness of the resulting glass cloth composites were about 150-170 μm. These composites were also thermally cured. Such a glass cloth composite from Example 7C was also prepared on a Cu foil. The peel strength of this composition on the Cu-foil was 3.7 N/cm. Dielectric properties of the cured materials are summarized in Table 6. It is evident from this data that the low loss properties were observed for these compositions that are suitable for various Cu-clad laminate applications.

TABLE 6

| Example | | Glass | | Dk at | Df at |
|---|---|---|---|---|---|
| No. | Polymer | Cloth | Cure Condition | 10 GHz | 10 GHz |
| Example | pHexNB | No | 190° C./45 min | 2.26 | 0.0020 |
| 7A | | | | | |
| Example | pHexNB | No | 2000 mJ/cm² | 2.35 | 0.0017 |
| 7B | | | | | |
| Example | pHexNB | Yes | 190° C./45 min | 2.76 | 0.0022 |
| 7C | | | | | |
| Example | p(NB/HexNB) | No | 190° C./45 min | 2.15 | 0.0016 |
| 7D | | | | | |
| Example | p(NB/HexNB) | Yes | 190° C./45 min | 2.66 | 0.0018 |
| 7E | | | | | |

### Example 8

### Reliability at High Temperature Storage

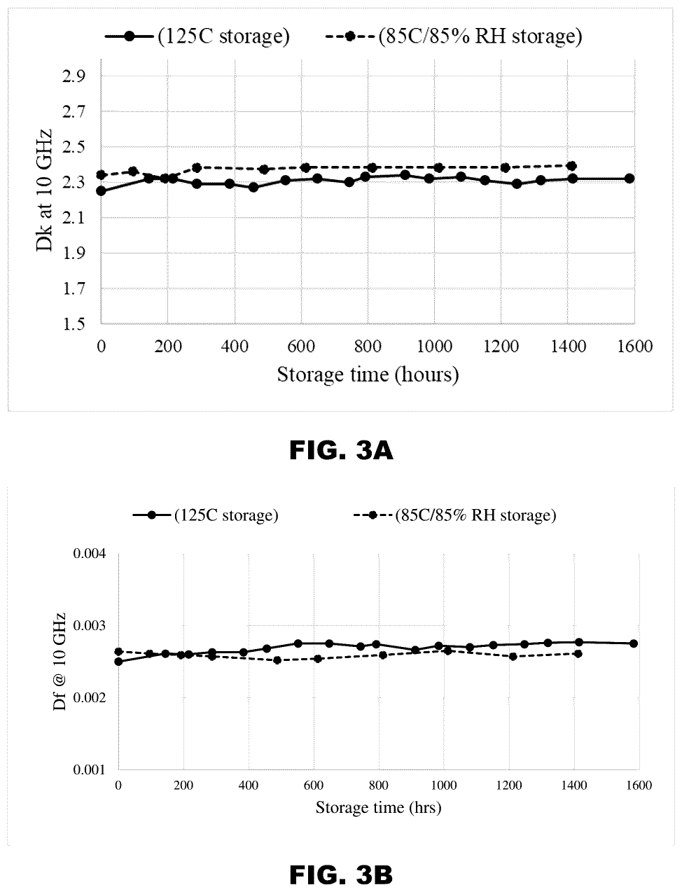

To the composition of Example 7A was added Irganox-1076 (1.75 pphr) and Irgafos-168 (0.5 pphr). Using this composition films (120-135 μm thickness) were prepared on a glass substrate by doctor blading and heating to 90° C. for 40 minutes in an oven under nitrogen atmosphere to remove any residual solvent. These films were cured at 150° C. for 45 minutes in an oven under vacuum. Dielectric measurements at 10 GHz were taken periodically for these films after being exposed to 125° C. storage in air (Example 8A) and exposure to 85° C./85% relative humidity (Example 8B) over 1400-1600 hours. FIG. 3A and FIG. 3B show the Dk and Df of these films under these accelerated aging conditions. It is quite evident from the data presented in FIG. 3A and FIG. 3B, Dk and Df did not change appreciably indicating that they have excellent reliability. Dk of the film samples remained 2.31±0.02 and 2.37±0.02 at 125° C. and 85° C./85% RH (relative humidity) storage respectively while Df remained 0.0027±0.0001 and 0.0026±0.00004 at 125° C. and 85° C./85% RH (relative humidity) storage, respectively. This study demonstrates that excellent reliability of dielectric properties suitable for various applications such as mmWave Radar Antenna for automotive can be obtained employing the compositions of this invention. Since functionalities such as olefin, acrylate or maleimide are not necessary in both polymer and tackifiers or it is not necessary to include reactive cross-linkers to generate cross-linked network for a thermoset in this invention, low reactivity to oxygen may be maintained during the high temperature conditions.

### Example 9

### Dielectric and Thermomechanical Properties

A copolymer, poly(NB/HexNB) (79/21 molar ratio, having a M_{w} of 168,000; Mₙ of 52,800; and PDI of 3.2), was dissolved in mesitylene to prepare 20 wt. % solution for Example 9A. A copolymer, poly(NB/HexNB) (90/10 molar ratio, having a M_{w} of 3,740; Mₙ of 1,370; and PDI of 2.7) suitable for resin flow during processing due to its low molecular weight was dissolved in mesitylene to prepare 50 wt. % solution for Example 9B. To each of these solutions were added PCG-1 diazirine (7.5 pphr). The composition from Example 9A was doctor bladed on a glass substrate and the solvent removed (B-staged) at 80° C. for 1 hour in an oven under nitrogen atmosphere to generate a film having a thickness of about 100 μm. This film was cured at 160° C. for 1 hour under nitrogen atmosphere in an oven. A low loss NE-glass cloth (from Nittobo, Style #1280 having a thickness of about 0.050 mm) was wetted with the composition of Example 9B, and the solvent removed (B-staged) at 80° C. for 1 hour in an oven under nitrogen atmosphere. Part of this glass cloth composite was cured at 160° C. for 1 hour under nitrogen atmosphere in an oven to generate a glass cloth composite of about 100 μm thickness (Example 9B1). Another part of the B-staged glass cloth composite was cured at 160° C. for 1 hour while pressing the sample at 5 MPa pressure. The temperature of the pressed sample was increased from ambient temperature to 160° C. in about 15 minutes during this cure step. A resin flow has occurred during this step impregnating the glass cloth to generate a composite of about 50-60 μm (Example 9B2). Dielectric and thermo-mechanical measurements (by TGA, TMA, DMA and Instron) of the cured samples generated from each of Example 9A and Example 9B are summarized in Table 7.

TABLE 7

| | |
|---|---|
| Example 9A | Example 9B1 |

| Dk at 10 GHz | 2.37 | | 2.76 |
|---|---|---|---|
| Df at 10 GHz | 0.0015 | | 0.0018 |
| T_{g} (TMA) | 229° | C. | 145, 205 |
| T_{g} (DMA) | 255° | C. | 155, 206 |
| CTE | 107 | ppm/K | 9 |
| T_{d5} (TGA) | 325° | C. | 292 |
| Young's Modulus (Instron) | 2.3 | GPa | 1.1 GPa |
| Storage Modulus (DMA) | 3.1 | GPa | 3.8 GPa |

| | | |
|---|---|---|
| Tensile Strength (Instron) | 48 | 32 |
| ETB (Instron) | 4% | 7% |

### Example 10

### Peel Strength Measurements

A homopolymer, poly(HexNB) (having a M_{w} of 147,100; Mₙ of 54,800; and PDI=2.7), was dissolved in decane to prepare 20 wt. % solution. This solution was doctor bladed on a glass substrate and heated to 150° C. for 1 hour to remove solvent on a hotplate resulting in a film having a thickness of about 150 μm.

Various diazirines as summarized in Table 8 were dissolved in TFT to make 5 wt. % solutions. Cu-foils (Mitsui, CF-14X-SV-18) were wetted with these diazirine solutions and heated to 90° C. for 20 minutes.

Rectangular pieces of poly(HexNB) films as prepared above were sandwiched between the treated Cu-foils and heated to 200° C. while pressing at 5-7 MPa for 1.5 hours. The pressure was released, and the samples were allowed to cool to ambient temperature. Peel strengths of the films attached to Cu-foils were measured at 90-deg tilt. Table 8 lists the peel strengths measured by an average of 5 maximum peaks method. Both the average peel strengths as well as the highest peel strength registered were recorded. Cu-foils coated with PCG-1 or PCG-2 had higher peel strengths than the untreated foil or the foils coated with Comp. PCG-A or Comp. PCG-B.

TABLE 8

| Example No. | Cu treated with | Peel Strength (max) | Peel Strength (average) |
|---|---|---|---|
| Example 10A | None | 2.1 N/cm | 1.4 N/cm |
| Example 10B | Comp. PCG-A | 3.1 N/cm | 2.6 N/cm |
| Example 10C | Comp. PCG-B | 4.6 N/cm | 3.2 N/cm |
| Example 10D | PCG-1 | 7.5 N/cm | 4.5 N/cm |
| Example 10E | PCG-2 | 9.3 N/cm | 5.5 N/cm |

### Example 11

Photo Contrast of Poly(HexNB) with Various Diazirines

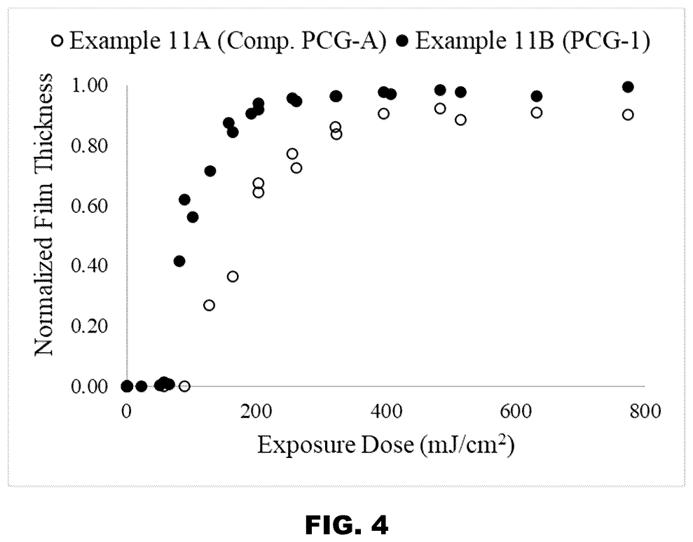

A homopolymer, poly(HexNB) (having a M_{w} of 147,050; Mₙ of 54,800; and PDI of 2.7) was dissolved in mesitylene to prepare 20 wt. % solution. To 5 g solutions containing 1 g of the polymer were added 0.00024 moles of diazirine cross-linkers Comp. PCG-A (0.1 g, Example 11A), PCG-1 (0.12 g, Example 11B), PGC-2 (0.14 g, Example 11C) and PCG-3 (0.19 g, Example 11D). Each of the compositions was further diluted with mesitylene (5 g) and filtered using 0.45 μm PTFE filters. Films were generated by spin coating these compositions on 4″ thermal oxide silicon wafers at 2400 rpm spin speed followed by heating to 80° C. for 3.5 minutes (soft bake) on a hotplate to remove the solvent which resulted in films having thickness of about 1.23 μm (from Example 11A containing Comp. PCG-A), 1.34 μm (from Example 11B containing PCG-1), 1.28 μm (from Example 11C containing PCG-2) and 1.51 μm (from Example 11D containing PCG-3). The films were exposed to 365 nm radiation using a variable density photo mask at a 0-1000 mJ/cm² dose range. The exposed films were developed with mesitylene for 40 seconds. The remaining film thicknesses of the imaged wafers were measured, and the data obtained were used to construct contrast curves (Film thicknesses normalized to the initial film thickness vs. exposure dose). FIG. 4 compares the contrast curves of films from Example 11A with Example 11B. It is evident from these results that PCG-1 has a higher photo activity and a higher contrast at 365 nm than Comp. PCG-A. The contrast (y) of these photosensitive films to photo-imaging were estimated based on the equation-1 using the dose at which the films start to cure Do (i.e., begins to become insoluble to mesitylene development), dose at which films are fully cured D100 (i.e., highest film thickness retention after mesitylene development). The results are listed in Table 9. The photo speeds were also estimated as the dose at which images (lines, pillars, and holes) are formed at good quality (no residues or wash off of the features). The compositions containing PCG-1, PCG-2 and PCG-3 have higher photo speeds than the composition containing Comp. PCG-A. The contrasts of these photo sensitive compositions are comparable and the Example 11B features slightly higher contrast.

$$γ = {( {log}_{10} ( {D}_{100} / {D}_{0} ) )}^{- 1} \qquad Equation 1$$

TABLE 9

| | | D₀ | D₁₀₀ | Photo speed | |
|---|---|---|---|---|---|
| Example No. | diazirine | (mJ/cm²) | (mJ/cm²) | (mJ/cm²) | Contrast (γ) |
| Example 11A | Comp. PCG-A | 73 | 301 | 400 | 1.6 |
| Example 11B | PCG-1 | 44 | 160 | 250 | 1.8 |
| Example 11C | PCG-2 | 54 | 246 | 325 | 1.5 |
| Example 11D | PCG-3 | 42 | 227 | 325 | 1.4 |

### Example 12

### Photo Imaging Studies

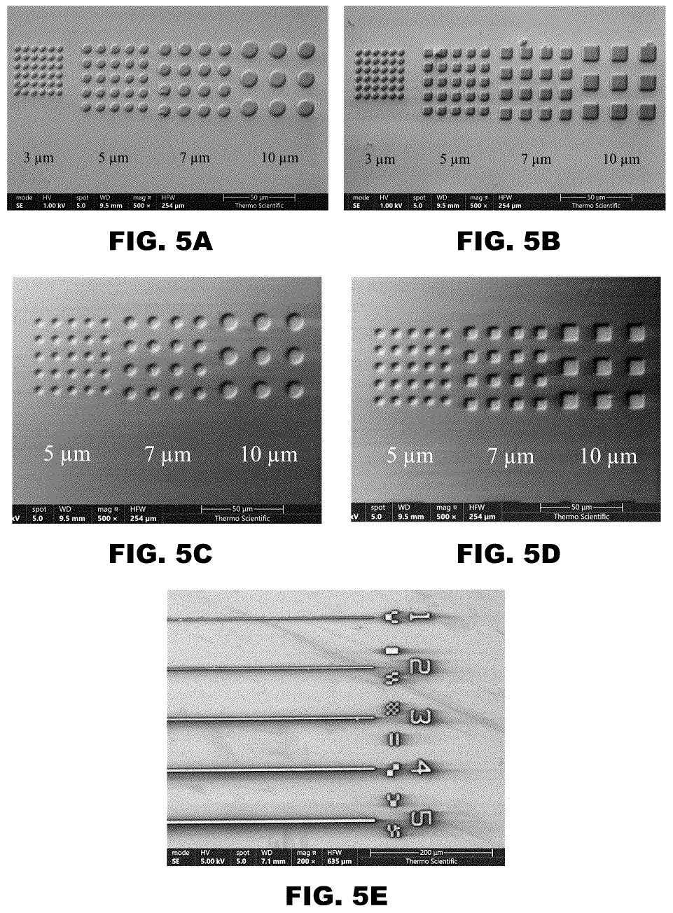

A homopolymer, poly(HexNB) (having a M_{w} of 130,500; Mₙ of 54,850; and PDI of 2.4), was dissolved in mesitylene to prepare 20 wt. % solution. PCG-1 (15 pphr) was added to 5 g sample (1 g pHexNB), diluted with mesitylene (5 g) and filtered through 0.45 μm PTFE filter (designated as Example 12B). A separate composition containing Comp. PCG-A was also made (designated as Example 12A). A film of each of these compositions were generated by spin coating onto a 4″ thermal oxide silicon wafer at 2400 rpm and soft baking at 80° C. for 3.5 minutes to remove the solvent resulting in a film having thickness of 0.90 μm. The wafer was exposed to 365 nm radiation (800 mJ/cm² exposure dose) through a photo-mask capable of generating lines, pillars, and vias. The exposed wafer was developed with mesitylene two times for 25 seconds each and dried with a stream of nitrogen. SEM images were taken for 3-20 μm lines, pillars and vias and shown in FIGS. 5A and 5B (pillars), FIGS. 5C and 5D (vias) and FIG. 5E (lines). Table 10 lists the photo imaging characteristics comparing Comp. PCG-A with PCG-1. Overall, PCG-1 gave lower bright field loss (BFL) measured by comparing the film thicknesses (FT) before and after exposure which is in consistent with the contrast curves shown in FIG. 4.

TABLE 10

| | | | | Resolution | Resolution | Resolution |
|---|---|---|---|---|---|---|
| Example No. | Diazirine | FT (μm) | BFL | (Lines) | (Pillars) | (Vias) |
| Example 13A | Comp. | 0.84 μm | 12% | 1 μm | 3 μm | 5 μm |
| | PCG-A | | | | | |
| Example 13B | PCG-1 | 0.85 μm | 1% | 1 μm | 3 μm | 5 μm |

FT—film thickness;
BFL—bright field loss

### Example 13

### Comparison of the Properties Containing Different Diazirines

Table 11 summarizes the ranking of several properties important for generating thermosets by photo or thermal processes suitable for various applications. Specifically, Table 11 summarizes various properties measured in various examples described above. In general PCG-1 was found to exhibit superior properties when compared with either one of the prior art diazirines, namely, Comp. PCG-A or Comp. PCG-B.

TABLE 11

| | Thermal | Photo | Photo | Dk at | Df at | Peel |
|---|---|---|---|---|---|---|
| Diazirine | Cure | Speed | Imaging | 10 GHz | 10 GHz | Strength |
| Comp. PCG-A | Moderate | Medium | Good | Moderate | Poor | Medium |
| Comp. PCG-B | Low | Low | Poor | Good | Good | Low |
| PCG-1 | High | High | Good | Moderate | Moderate | High |

Although the invention has been illustrated by certain of the preceding examples, it is not to be construed as being limited thereby; but rather, the invention encompasses the generic area as hereinbefore disclosed. Various modifications and embodiments can be made without departing from the spirit and scope thereof.

What is claimed is:

1. A composition comprising:
a) a polycycloolefinic polymer comprising at least one repeat unit represented by formula (IA), said repeat unit is derived from a monomer of formula (I): 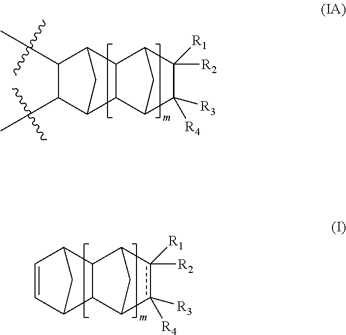
wherein: [symbol]
denotes a place of bonding with another repeat unit;
m is 0, 1 or 2; [symbol]
is a single bond or a double bond;
R₁, R₂, R₃ and R₄ are the same or different and each independently selected from the group consisting of hydrogen, methyl, ethyl, linear or branched (C₃-C₁₆)alkyl, (C₃-C₁₀)cycloalkyl, (C₆-C₁₂)bicycloalkyl, (C₆-C₁₂)aryl and (C₆-C₁₂)aryl(C₁-C₆)alkyl; or
one of R₁ and R₂ taken together with one of R₃ and R₄ and the carbon atoms to which they are attached to form a substituted or unsubstituted (C₅-C₁₄)cyclic, (C₅-C₁₄)bicyclic or (C₅-C₁₄)tricyclic ring optionally containing one or more double bonds;
b) a diazirine selected from the group consisting of:
a bis-diazirine of formula (IIA): 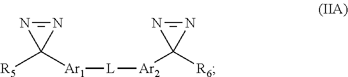
a tris-diazirine of formula (IIB): 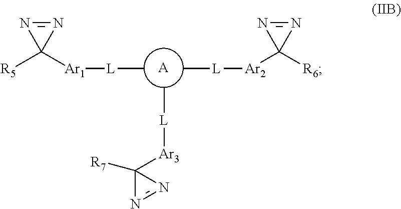
and
a tetrakis-diazirine of formula (IIC): 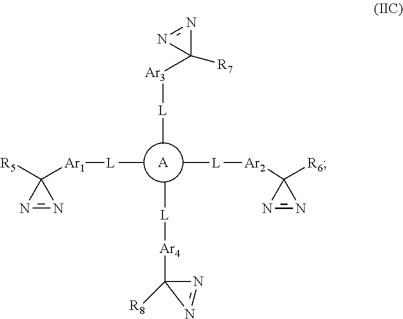
wherein:
L is selected from the group consisting of —O—(C₁-C₁₆)alkylene-O—, —O—(CH₂)₂—O—(C₆-C₁₂)arylene-O—(CH₂)₂—O— and —O—(CH₂)₃—O—(C₆-C₁₂)arylene-O—(CH₂)₃—O—;
A is a trivalent or tetravalent aliphatic, cycloaliphatic or aromatic moiety;
Ar₁, Ar₂, Ar₃ and Ar₄ are the same or different and each independently selected from the group consisting of (C₆-C₁₂)arylene and (C₆-C₁₂) heteroarylene group optionally substituted with a group selected from (C₁-C₄)alkyl, (C₁-C₄)alkoxy, (C₆-C₁₀)aryl, (C₆-C₁₂)aryloxy, (C₆-C₁₂)aryl(C₁-C₄)alkyl and (C₆-C₁₂)aryl(C₁-C₄)alkyloxy; and
R₅, R₆, R₇ and R₅ are the same or different and each independently selected from the group consisting of perfluoro (C₁-C₆)alkyl and perfluoro (C₃-C₇)cycloalkyl;
wherein a film formed from the composition containing at least one of the diazirine of formula (IIA), (IIB) or (IIC) at an amount of at least about 2.5 parts per 100 parts of the polymer of formula (I) has a dielectric constant (Dk) less than 2.4 at a frequency of 10 GHz, a glass transition temperature greater than 210° C. and a coefficient of thermal expansion (CTE) less than 200 ppm/K.

2. The composition according to claim 1, wherein
m is 0 or 1; [symbol]
is a single bond;
R₁, R₂, R₃ and R₄ are the same or different and each independently selected from the group consisting of hydrogen, n-butyl, n-hexyl, n-octyl, n-decyl, cyclohexyl, norbornyl, phenyl and phenethyl.

3. The composition according to claim 1, wherein the polymer is derived from one or more monomers of formula (I) selected from the group consisting of:

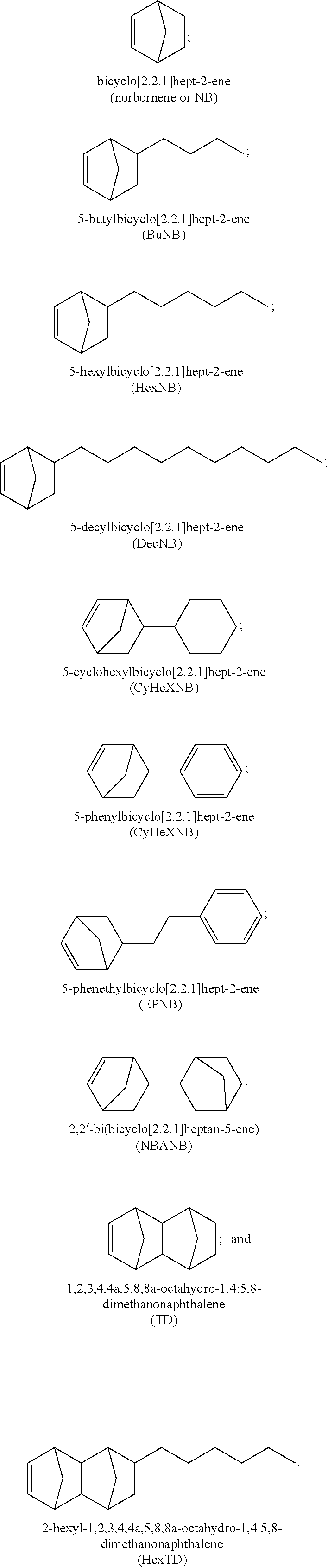

4. The composition according to claim 1, wherein the polymer is a homopolymer.

5. The composition according to claim 1, wherein the polymer is a copolymer.

6. The composition according to claim 1, wherein:
L is selected from the group consisting of —O(CH₂)₂O—, —O(CH₂)₄O—, —O(CH₂)₆O—, —O(CH₂)₈O—, —O(CH₂)₁₀O—, —O(CH₂)₂O—(C₆H4)—O(CH₂)₂O— and —O(CH₂)₂O—(C₆H4)—(C₆H4)—O(CH₂)₂O—;
A is selected from the group consisting of trivalent or tetravalent (C₁-C₈)alkyl, (C₃-C₈)cycloalkyl, (C₆-C₁₂)aryl and (C₆-C₁₂)aryl(C₁-C₄)alkyl;
Ar₁, Ar₂, Ar₃ and Ar₄ are the same or different and each independently selected from the group consisting of phenylene, biphenylene, naphthalene, pyridine and quinoline optionally substituted with a group selected from the group consisting of methyl, ethyl, propyl, butyl, methoxy, ethoxy, propoxy, butoxy, phenyl, phenoxy, phenethyl and phenethoxy; and
R₅, R₆, R₇ and R₅ are the same or different and each independently selected from the group consisting of trifluoromethyl, pentafluoroethyl, heptafluoropropyl and perfluorocyclohexyl.

7. The composition according to claim 1, wherein the diazirine of formula (IIA) is selected from the group consisting of:

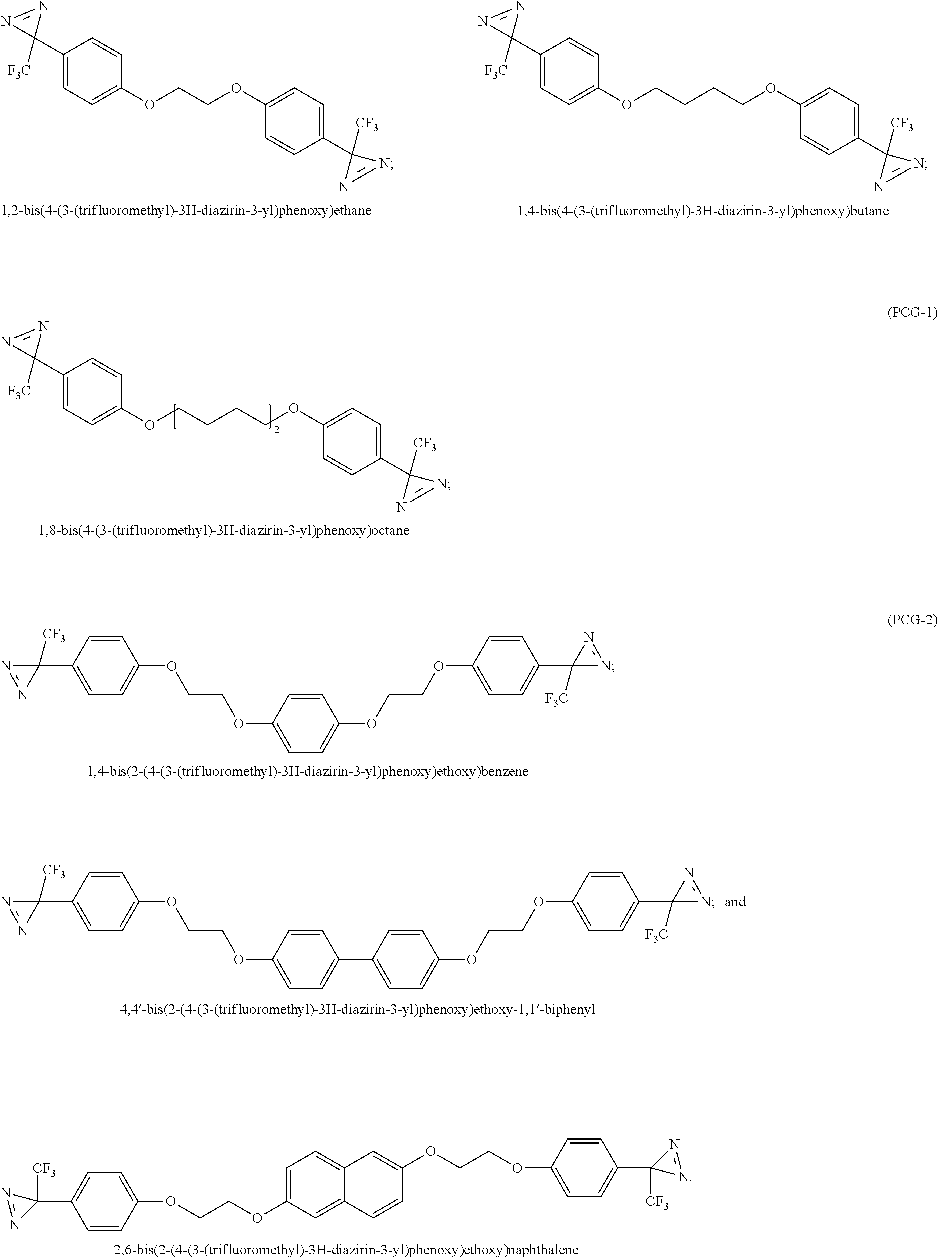

8. The composition according to claim 1, wherein the diazirine of formula (IIB) is selected from the group consisting of:

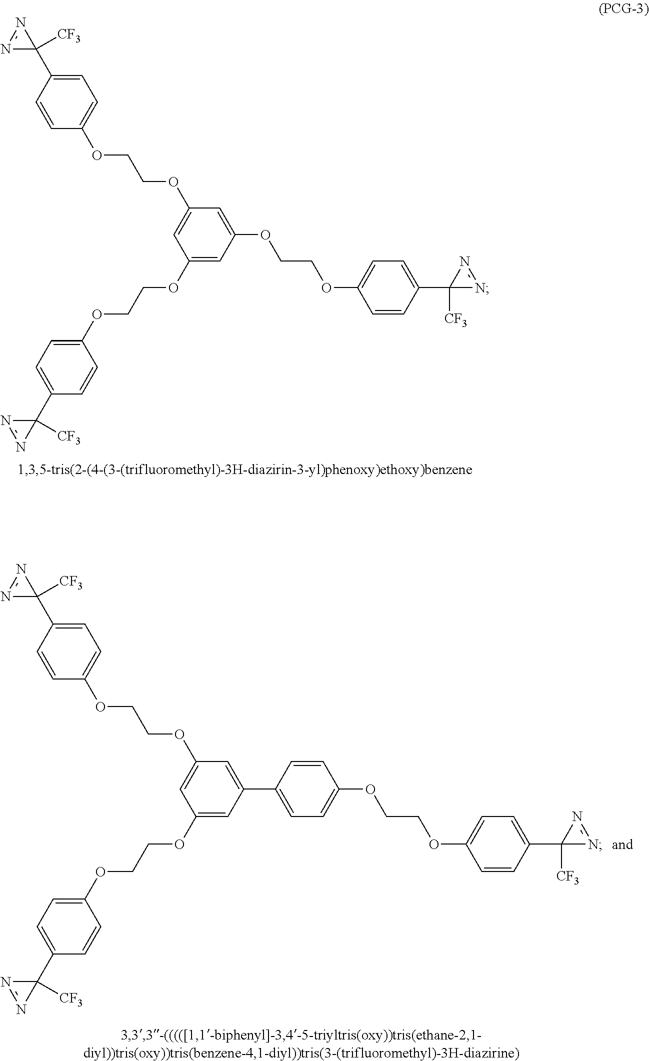 [SMILES: FC(F)(F)C1(c2ccc(OCCOc3cc(OCCOc4ccc(C5(C(F)(F)F)N=N5)cc4)cc(OCCOc4ccc(C5(C(F)(F)F)N=N5)cc4)c3)cc2)N=N1 ; FC(F)(F)C1(c2ccc(OCCOc3ccc(-c4cc(OCCOc5ccc(C6(C(F)(F)F)N=N6)cc5)cc(OCCOc5ccc(C6(C(F)(F)F)N=N6)cc5)c4)cc3)cc2)N=N1]

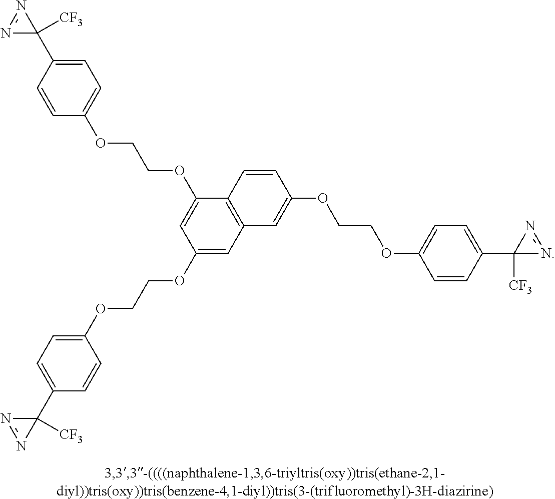 [SMILES: FC(F)(F)C1(c2ccc(OCCOc3ccc4c(OCCOc5ccc(C6(C(F)(F)F)N=N6)cc5)cc(OCCOc5ccc(C6(C(F)(F)F)N=N6)cc5)cc4c3)cc2)N=N1]

9. The composition according to claim 1, wherein the diazirine of formula (IIC) is selected from the group consisting of:

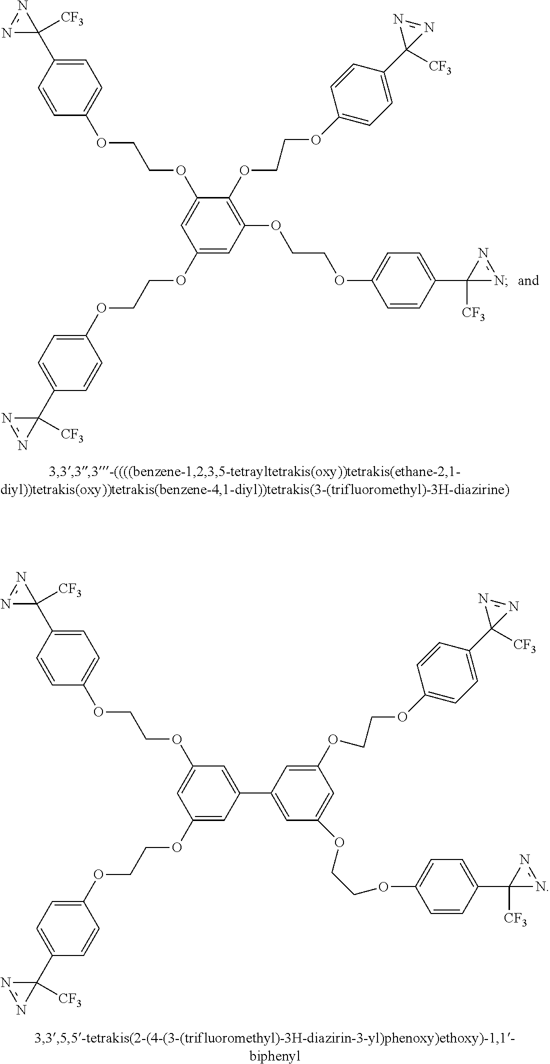 [SMILES: FC(F)(F)C1(c2ccc(OCCOc3cc(OCCOc4ccc(C5(C(F)(F)F)N=N5)cc4)c(OCCOc4ccc(C5(C(F)(F)F)N=N5)cc4)c(OCCOc4ccc(C5(C(F)(F)F)N=N5)cc4)c3)cc2)N=N1 ; FC(F)(F)C1(c2ccc(OCCOc3cc(OCCOc4ccc(C5(C(F)(F)F)N=N5)cc4)cc(-c4cc(OCCOc5ccc(C6(C(F)(F)F)N=N6)cc5)cc(OCCOc5ccc(C6(C(F)(F)F)N=N6)cc5)c4)c3)cc2)N=N1]

10. The composition according to claim 1, which is selected from the group consisting of:
a solution of homopolymer of (5-hexylbicyclo[2.2.1]hept-2-ene) (polyHexNB) and 1,8-bis(4-(3-(trifluoromethyl)-3H-diazirin-3-yl)phenoxy)octane (PCG-1);
a solution of homopolymer of (5-hexylbicyclo[2.2.1]hept-2-ene) (polyHexNB) and 1,4-bis(2-(4-(3-(trifluoromethyl)-3H-diazirin-3-yl)phenoxy)ethoxy)benzene (PCG-2);
a solution of homopolymer of (5-hexylbicyclo[2.2.1]hept-2-ene) (polyHexNB) and 1,3,5-tris(2-(4-(3-(trifluoromethyl)-3H-diazirin-3-yl)phenoxy)ethoxy)benzene (PCG-3);
a solution of copolymer of norbornene and (5-hexylbicyclo[2.2.1]hept-2-ene) (copolyNB/HexNB) and 1,8-bis(4-(3-(trifluoromethyl)-3H-diazirin-3-yl)phenoxy)octane (PCG-1);
a solution of copolymer of norbornene and (5-hexylbicyclo[2.2.1]hept-2-ene) (copolyNB/HexNB) and 1,4-bis(2-(4-(3-(trifluoromethyl)-3H-diazirin-3-yl)phenoxy)ethoxy)benzene (PCG-2); and
a solution of copolymer of norbornene and (5-hexylbicyclo[2.2.1]hept-2-ene) (copolyNB/HexNB) and 1,3,5-tris(2-(4-(3-(trifluoromethyl)-3H-diazirin-3-yl)phenoxy)ethoxy)benzene (PCG-3).

11. A film formed from the composition according to claim 1, which is photoimageable.

12. The film according to claim 11, which has dielectric constant (Dk) of 2.26 to 2.57 at a frequency of 10 GHz, a glass transition temperature from about 220° C. to about 280° C. and a coefficient of thermal expansion (CTE) from about 180 ppm/K to about 200 ppm/K.

13. The composition according to claim 1 further comprising one or more tackifiers.

14. The composition according to claim 12, wherein the tackifier is a fully hydrogenated hydrocarbon resin.

15. The composition according to claim 12, wherein the tackifier is selected from the group consisting of hydrogenated dicyclopentadiene polymer, hydrogenated ethylene-propylene-dicyclopentadiene terpolymer,

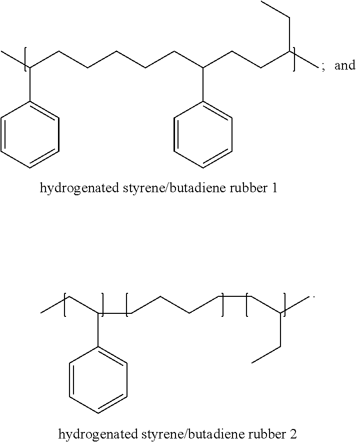

16. A composition comprising:
a) a polycycloolefinic polymer comprising at least one repeat unit represented by formula (IA), said repeat unit is derived from a monomer of formula (I): 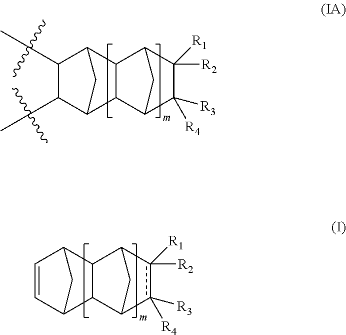
wherein: [symbol]
denotes a place of bonding with another repeat unit;
m is 0, 1 or 2; [symbol]
is a single bond or a double bond;
R₁, R₂, R₃ and R₄ are the same or different and each independently selected from the group consisting of hydrogen, methyl, ethyl, linear or branched (C₃-C₁₆)alkyl, (C₃-C₁₀)cycloalkyl, (C₆-C₁₂)bicycloalkyl, (C₆-C₁₂)aryl and (C₆-C₁₂)aryl(C₁-C₆)alkyl; or
one of R₁ and R₂ taken together with one of R₃ and R₄ and the carbon atoms to which they are attached to form a substituted or unsubstituted (C₅-C₁₄)cyclic, (C₅-C₁₄)bicyclic or (C₅-C₁₄)tricyclic ring optionally containing one or more double bonds;
b) a diazirine selected from the group consisting of:
a bis-diazirine of formula (IIA): 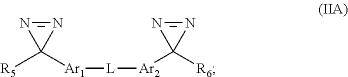
a tris-diazirine of formula (IIB): 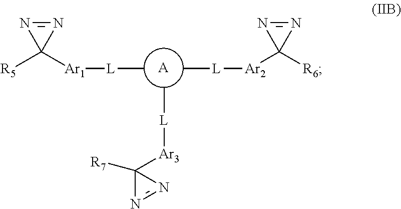
and
a tetrakis-diazirine of formula (IIC): 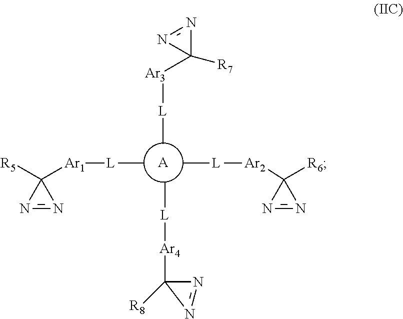
wherein:
L is selected from the group consisting of —O—(C₁-C₁₆)alkylene-O—, —O—(CH₂)₂—O—(C₆-C₁₂)arylene-O—(CH₂)₂—O— and —O—(CH₂)₃—O—(C₆-C₁₂)arylene-O—(CH₂)₃—O—;
A is a trivalent or tetravalent aliphatic, cycloaliphatic or aromatic moiety;
Ar₁, Ar₂, Ar₃ and Ar₄ are the same or different and each independently selected from the group consisting of (C₆-C₁₂)arylene and (C₆-C₁₂) heteroarylene group optionally substituted with a group selected from (C₁-C₄)alkyl, (C₁-C₄)alkoxy, (C₆-C₁₀)aryl, (C₆-C₁₂)aryloxy, (C₆-C₁₂)aryl(C₁-C₄)alkyl and (C₆-C₁₂)aryl(C₁-C₄)alkyloxy; and
R₅, R₆, R₇ and R₅ are the same or different and each independently selected from the group consisting of perfluoro (C₁-C₆)alkyl and perfluoro (C₃-C₇)cycloalkyl; and
c) a hydrogenated tackifier.

17. The composition according to claim 16, wherein the polymer is derived from one or more monomers of formula (I) selected from the group consisting of:

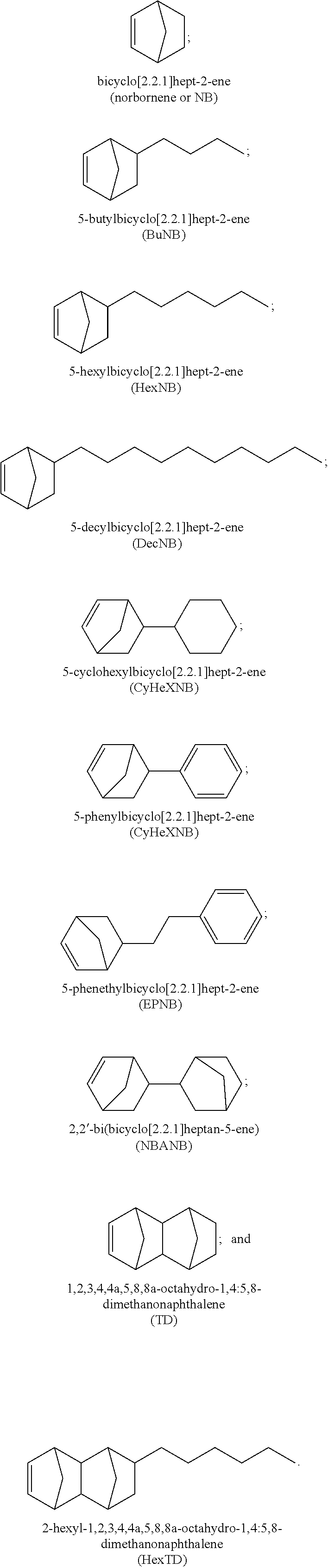

18. The composition according to claim 16, wherein the diazirine of formulae (IIA), (IIB) or (IIC) is selected from the group consisting of:

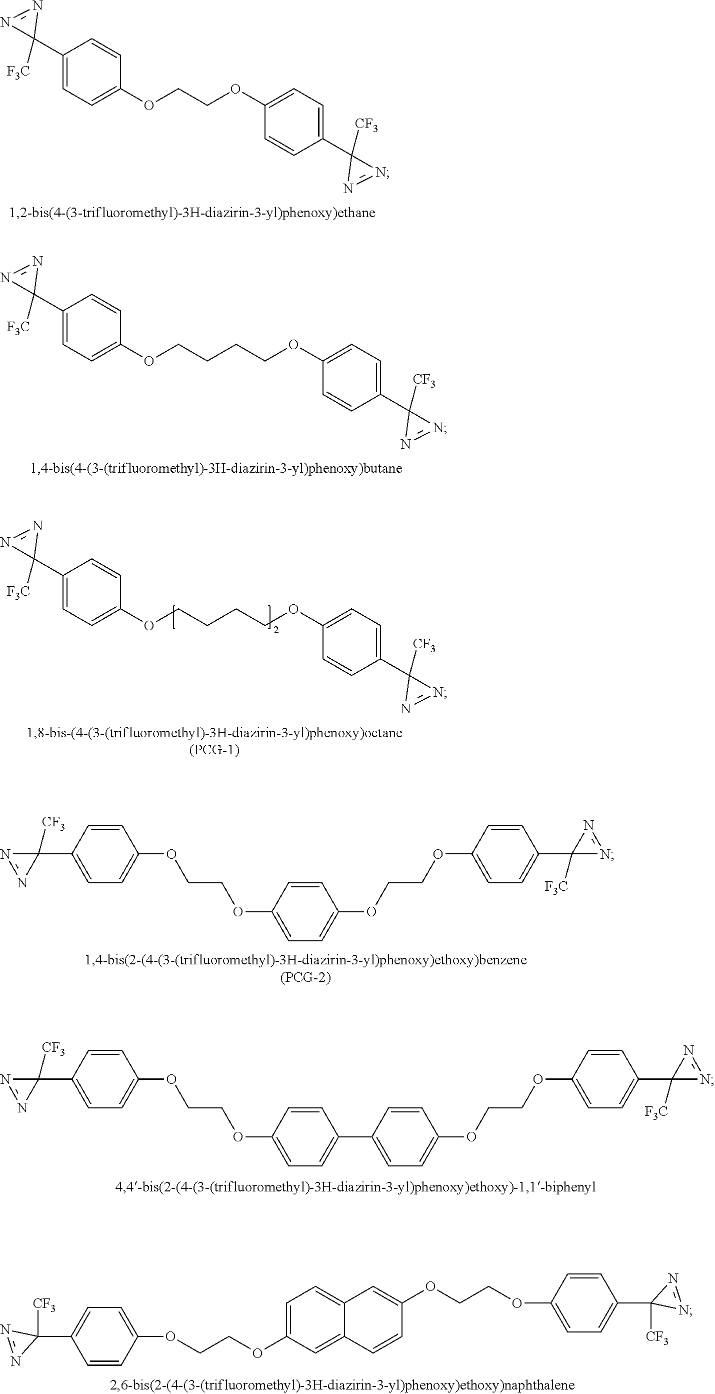

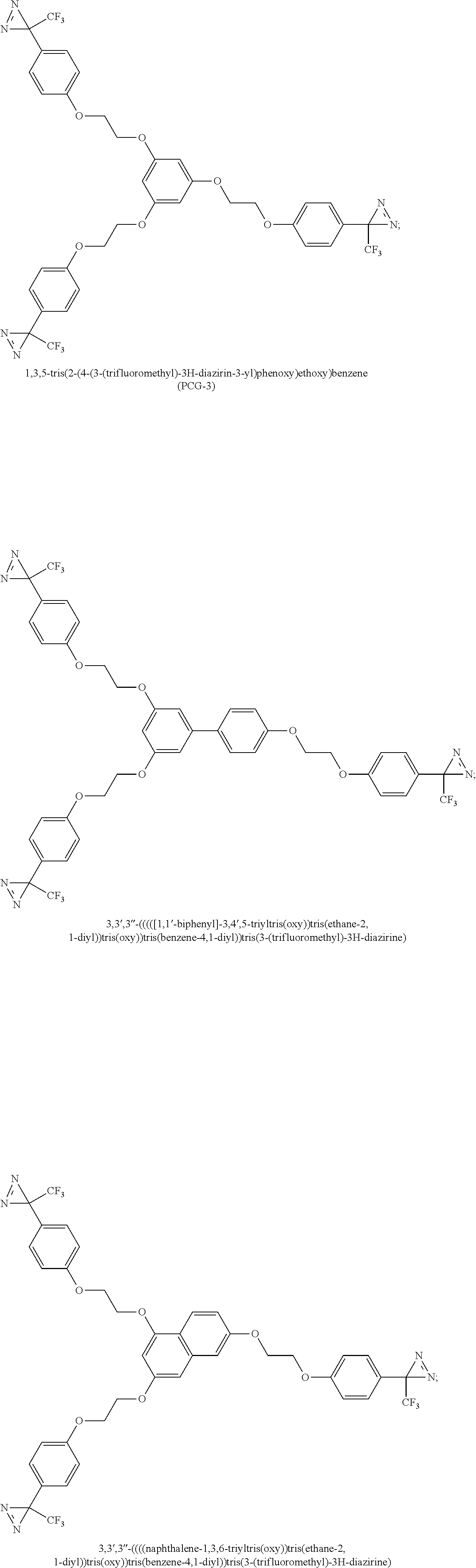 [SMILES: FC(F)(F)C1(c2ccc(OCCOc3cc(OCCOc4ccc(C5(C(F)(F)F)N=N5)cc4)cc(OCCOc4ccc(C5(C(F)(F)F)N=N5)cc4)c3)cc2)N=N1 ; FC(F)(F)C1(c2ccc(OCCOc3ccc(-c4cc(OCCOc5ccc(C6(C(F)(F)F)N=N6)cc5)cc(OCCOc5ccc(C6(C(F)(F)F)N=N6)cc5)c4)cc3)cc2)N=N1 ; FC(F)(F)C1(c2ccc(OCCOc3ccc4c(OCCOc5ccc(C6(C(F)(F)F)N=N6)cc5)cc(OCCOc5ccc(C6(C(F)(F)F)N=N6)cc5)cc4c3)cc2)N=N1]

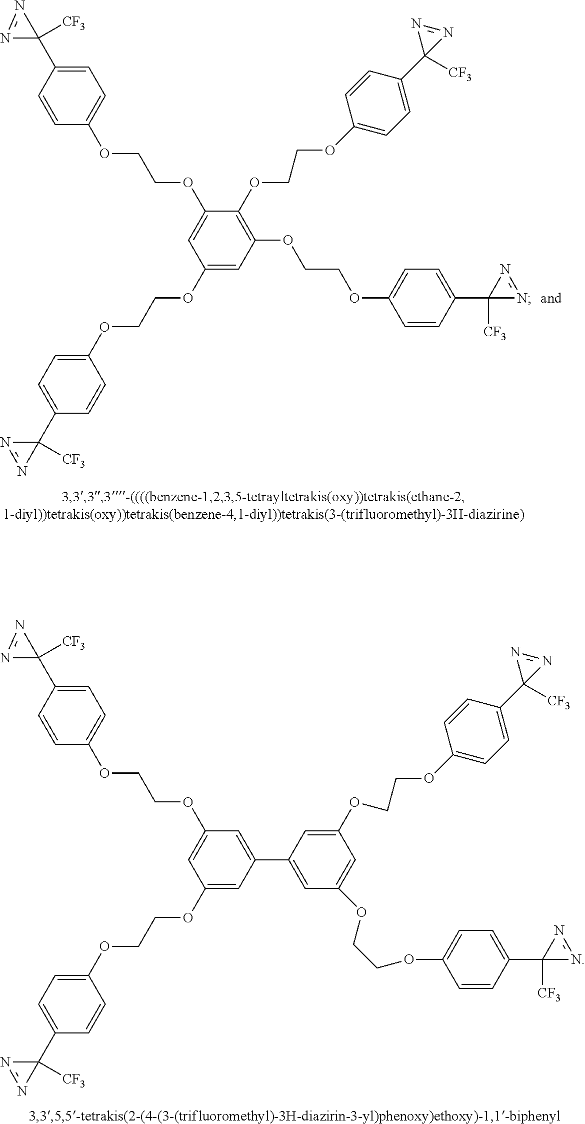 [SMILES: FC(F)(F)C1(c2ccc(OCCOc3cc(OCCOc4ccc(C5(C(F)(F)F)N=N5)cc4)c(OCCOc4ccc(C5(C(F)(F)F)N=N5)cc4)c(OCCOc4ccc(C5(C(F)(F)F)N=N5)cc4)c3)cc2)N=N1 ; FC(F)(F)C1(c2ccc(OCCOc3cc(OCCOc4ccc(C5(C(F)(F)F)N=N5)cc4)cc(-c4cc(OCCOc5ccc(C6(C(F)(F)F)N=N6)cc5)cc(OCCOc5ccc(C6(C(F)(F)F)N=N6)cc5)c4)c3)cc2)N=N1]

19. The composition according to claim 16, wherein the hydrogenated tackifier is selected from the group consisting of hydrogenated dicyclopentadiene polymer, hydrogenated ethylene-propylene-dicyclopentadiene terpolymer,

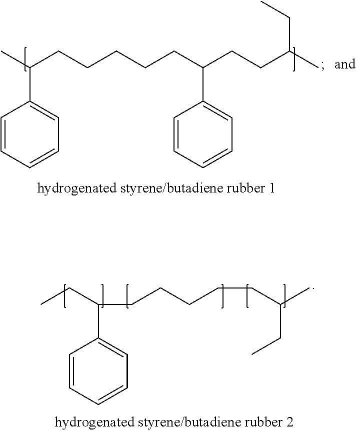

20. A copper-clad laminate formed from the composition of claim 16.
